(19) United States
(12) Patent Application Publication
(10) Pub. No.: US 2024/0405054 A1
(43) Pub. Date: Dec. 5, 2024

(54) MONOLITHIC ARRAY CHIP

(71) Applicant: EPISTAR CORPORATION, Hsinchu (TW)

(72) Inventors: Min-Hsun HSIEH, Hsinchu (TW); Chih-Ming WANG, Hsinchu (TW); Jan-Way CHIEN, Hsinchu (TW); Hui-Ching FENG, Hsinchu (TW); Yu-Chi WANG, Hsinchu (TW); Hsia-Ching CHENG, Hsinchu (TW)

(21) Appl. No.: 18/679,369

(22) Filed: May 30, 2024

Related U.S. Application Data
(60) Provisional application No. 63/556,338, filed on Feb. 21, 2024.
(60) Provisional application No. 63/524,771, filed on Jul. 3, 2023.
(60) Provisional application No. 63/471,078, filed on Jun. 5, 2023.

(51) Int. Cl. H01L 27/15; H01L 25/13; H01L 33/50

(52) U.S. Cl. CPC H01L 27/15; H01L 25/13; H01L 33/50

(57) ABSTRACT

A monolithic array chip comprises a first semiconductor layer; a common electrode located on the first semiconductor layer; a first light-emitting unit with a first electrode located on the first semiconductor layer; a second light-emitting unit with a second electrode located on the first semiconductor layer; a third light-emitting unit with a third electrode located on the first semiconductor layer, wherein the first light-emitting unit, the second light-emitting unit, and the third light-emitting unit are separated from each other by a trench.

### REFERENCE TO RELATED APPLICATION

This application claims the right of priority based on U.S. Provisional Application Ser. No. 63/471,078, filed on Jun. 5, 2023, U.S. Provisional Application Ser. No. 63/524,771, filed on Jul. 3, 2023, U.S. Provisional Application Ser. No. 63/556,338, filed on Feb. 21, 2024, and the content of which are hereby incorporated by references in their entireties.

### TECHNICAL FIELD

The application relates to a structure of a monolithic array chip and a manufacturing method thereof.

### DESCRIPTION OF BACKGROUND ART

The compound semiconductor device can be a semiconductor optoelectronic device, such as a light-emitting diode (LED) or a laser to convert the electrical energy to the optical energy, or a solar cell to convert the optical energy to the electrical energy. The semiconductor optoelectronic device can also be a power device or an acoustic wave device. Taking the light-emitting diode as an example, the light-emitting diode provides many benefits over other light sources, such as the small size, the durability, and the high efficiency. The LEDs can be used as the light sources in the display, such as the television, the computer monitor, the laptop, and the tablet. The light-emitting diode providing as the inorganic light source is widely used in various fields such as the display, the automotive lighting, and the general lighting. Since the micro-LED (uLED) comprising the III-V semiconductors has the advantages such as the small size (for example, a size of less than 100 μm, less than 50 μm, less than 10 μm, or less than 5 μm), the high-density packaging (the high-resolution), and the high brightness, it has been applied to various displays. The micro-LED capable of emitting the light in different colors (e.g., red, green, and blue) can be provided as a sub-pixel in the display such as the television.

Each sub-pixel in the micro-LED display is correspondingly arranged with a micro-LED. The micro-LED display needs a large amount of micro-LEDs arranged on a substrate. However, the size of the micro-LED is very small, so it is not easy to mount the micro-LED on the substrate, and it is also difficult to replace the defective LED with a good LED in the micro LED display.

### SUMMARY OF THE APPLICATION

A monolithic array chip comprises a first semiconductor layer; a common electrode located on the first semiconductor layer; a first light-emitting unit with a first electrode located on the first semiconductor layer; a second light-emitting unit with a second electrode located on the first semiconductor layer; a third light-emitting unit with a third electrode located on the first semiconductor layer, wherein the first light-emitting unit, the second light-emitting unit, and the third light-emitting unit are separated from each other by a trench.

### BRIEF DESCRIPTION OF THE DRAWINGS

The embodiments of the disclosure will be described in detail below with reference to the accompanying drawings. It should be noted that various features are not drawn to scale and are for illustrative purposes only. In fact, the dimensions of the elements may be enlarged or reduced to clearly demonstrate the technical features of the embodiments of the present disclosure.

FIG. 1 is a partially enlarged plan view of a display device 101 according to an embodiment of the present application.

FIG. 2 is a circuit structure diagram of the display device 101 according to an embodiment of the present application.

FIG. 3 illustrates a top view of the light-emitting device 1 and the monolithic array chip 1′ of the first embodiment.

FIG. 4 illustrates a top view of the light-emitting device 2 and the monolithic array chip 2′ of the second embodiment.

FIG. 5A illustrates a top view of the light-emitting device 3 and the monolithic array chip 3′ of the third embodiment.

FIGS. 5B-5C illustrate the perspective views of the plurality of light-emitting elements 3 and the plurality of monolithic array chips 3′ in FIG. 5A.

FIGS. 6A-6B illustrate the top views of the light-emitting devices 4, 4B and the monolithic array chip 4′, 4B′ of the fourth embodiment.

FIG. 7 illustrates a top view of the light-emitting device 5 and the monolithic array chip 5′ of the fifth embodiment.

FIG. 8 illustrates a top view of the light-emitting device 6 and the monolithic array chip 6′ of the sixth embodiment.

FIG. 9 illustrates a top view of the light-emitting device 7 and the monolithic array chip 7′ of the seventh embodiment.

FIG. 10 illustrates a top view of the light-emitting device 8 and the monolithic array chip 8′ of the eighth embodiment.

FIG. 11 illustrates a top view of the light-emitting device 9 and the monolithic array chip 9′ of the ninth embodiment.

FIG. 12 illustrates a top view of the light-emitting device 10 and the monolithic array chip 10′ of the tenth embodiment.

FIG. 13 illustrates the manufacturing method of the semiconductor stack 200.

FIG. 14 illustrates the manufacturing method of the trench TR along the line Y-Y′ in FIGS. 3-12.

FIGS. 15 to 16 illustrate the manufacturing method of the separation lane ISO along the line Y-Y′ in FIGS. 3-12.

FIG. 17 illustrates a cross-sectional view along the line Y-Y′ in FIGS. 3-12.

FIG. 18A illustrates a cross-sectional view along the line X-X′ in FIG. 6A and FIGS. 7-8.

FIG. 18B illustrates a cross-sectional view along the line X-X′ in FIG. 3-5A and FIG. 9.

FIG. 19 illustrates a cross-sectional view of the monolithic array chip 4′, 5′, 6′ along the line X-X′ and the line Y-Y′ in FIG. 6A and FIGS. 7-8.

FIG. 20 illustrates a cross-sectional view of the monolithic array chip 4′, 5′, 6′ along the line X-X′ and the line Y-Y′ in FIG. 6A and FIGS. 7-8 with a wavelength conversion layer in accordance with an embodiment of the present application.

FIG. 21 illustrates a cross-sectional view of the monolithic array chip 4′, 5′, 6′ along the line X-X′ and the line Y-Y′ in FIG. 6A and FIGS. 7-8 with a wavelength conversion layer in accordance with another embodiment of the present application.

FIG. 22 illustrates a cross-sectional view of the monolithic array chip 4′, 5′, 6′ in FIG. 6A and FIGS. 7-8 after removing the substrate and the undoped semiconductor layer.

FIG. 23 illustrates a cross-sectional view of the monolithic array chip 8′, 9′, 10′ along the line Y-Y′ in FIGS. 10-12.

FIG. 24 illustrates a cross-sectional view of the monolithic array chip 8′, 9′, 10′ in FIGS. 10-12 with a wavelength conversion layer.

FIG. 25 illustrates a cross-sectional view of the monolithic array chip 8′, 9′, 10′ in FIGS. 10-12 with a wavelength conversion layer.

FIG. 26 illustrates a partial top view of a light-emitting module 10000 including 1′, 2′, 3′, 4′, 5′, 6′, 7′, 8′, 9′, 10′ in accordance with an embodiment.

FIGS. 27-30 illustrate the cross-sectional views along the line X-X′ of FIGS. 3-9 in accordance with an embodiment of the present application.

FIG. 31 illustrates the light-emitting units 10, 20, 30 of the monolithic array chip 1′, 2′, 3′, 4′, 5′, 6′, 7′, 8′, 9′ or 10′ in FIGS. 3-12 having different peak wavelengths under different driving current densities in accordance with an embodiment of the present application.

FIGS. 32-35 illustrate the manufacturing method of the monolithic array chip 1′, 2′, 3′, 4′, 5′, 6′, 7′, 8′, 9′, 10′ according to an embodiment of the present application.

FIGS. 36A-36B illustrate that as the size of the light-emitting unit becomes smaller and smaller, the area occupied by the separation lanes on the wafer will become more and more under the same separation lane width.

FIG. 37 illustrates a conventional light-emitting device.

FIGS. 38A-38B illustrate a light-emitting device according to an embodiment of the present application.

### DETAILED DESCRIPTION OF PREFERRED EMBODIMENTS

The following disclosure provides many different embodiments for implementing different features of the present application. The following disclosure describes specific examples of each element and its arrangement to simplify the explanation. Of course, these specific examples are not limiting. For example, if the embodiment of the present disclosure describes that a first feature is formed on or above a second feature, it means that the first feature and the second feature are in direct contact, or additional features are formed between the first feature and the second feature such that the first feature and the second feature may not be in direct contact.

It should be understood that other operating steps may be performed before, between or after the method, and in other embodiments of the method, part of the operating steps may be replaced or omitted.

In addition, space-related words may be used, such as “under”, “below”, “lower”, “above”, “on”, “higher” and the related, these spatially related terms are used to facilitate the description of the relationship between one element or feature(s) and another element or feature(s) in the illustrations. These spatially related terms include the various orientations of the device in use or operation, and the orientation depicted in the drawings. When the device is rotated to different orientations (rotated 45 degrees or at any other orientation), the spatially relative adjectives used in the device will be interpreted in accordance with the rotated orientation. Furthermore, when it is said that a first material layer is located on or above a second material layer, it includes the situation where the first material layer and the second material layer are in direct contact, or there may be one or more other materials separated between them. In the case, there may not be direct contact between the first material layer and the second material layer. In some embodiments of the present disclosure, unless otherwise defined, terms related to joining and connecting, such as “connection” or “interconnection”, may mean that two structures are in direct contact, or may also mean that two structures are not in direct contact and there are other structures located between these two structures. And the terms about joining and connecting can also include the situation where both structures are movable or both structures are fixed.

In the specification, the terms “about”, “nearly”, “roughly”, “approximately”, “substantially”, “same”, and “similar” usually indicate within +15% of a characteristic value of a given value, or within +10%, or within +5%, or within +3%, or within +2%, or within +1%, or within the range of +0.5%. The quantities given here are approximate quantities, that is, in the absence of specific instructions for “about”, “nearly”, “roughly”, “approximately”, and “substantially”, they may still imply the meaning of “about”, “nearly”, “roughly”, “approximately”, and “substantially”.

It should be understood that, although the terms “first”, “second”, “third”, etc. are used herein to describe various elements, parts, regions, layers and/or sections, these elements, parts, regions, layers and/or segments should not be limited by these terms. These terms may only be used to distinguish one element, part, region, layer or section from another element, part, region, layer or section. Thus, a first element, part, region, layer or section discussed below could be termed a second element, part, region, layer or section without departing from the teachings of the present disclosure.

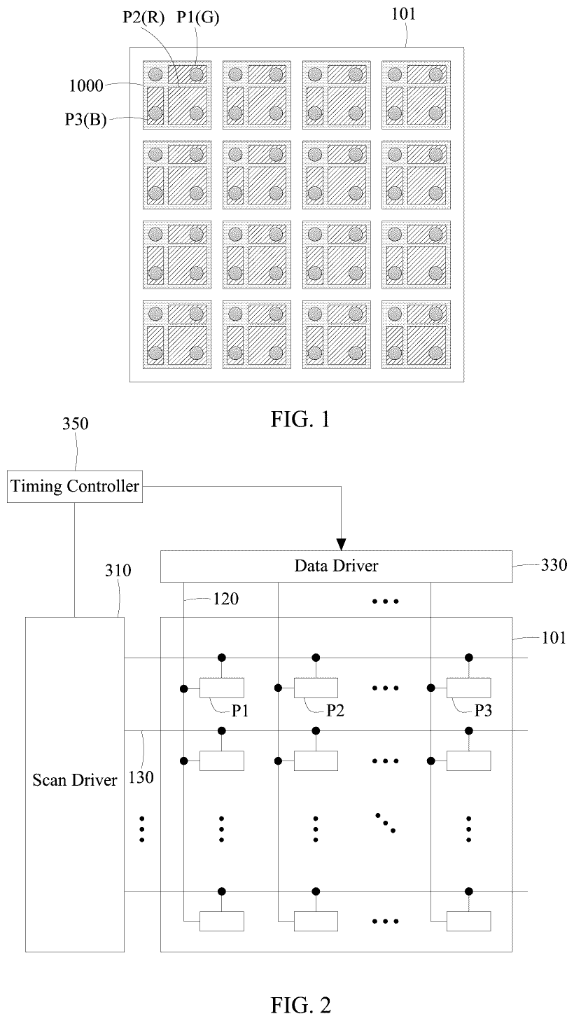

FIG. 1 is a partially enlarged plan view of a display device 101 according to an embodiment of the present application. FIG. 2 is a circuit structure diagram of the display device 101 according to an embodiment of the present application.

The display device 101 may be provided in various shapes, such as a polygon composed of straight lines, a circle or an ellipse composed of curves, or a semicircle or a semi-elliptical shape composed of straight lines and curves. In an embodiment of the present application, FIG. 1 illustrates a display device 101 having a rectangular shape.

The display device 101 comprises a plurality of pixels 1000 for displaying the image. Each pixel 1000 is the smallest unit for displaying the image. Each pixel 1000 can emit the white light and/or the color light. Each pixel 1000 comprises one sub-pixel emitting one color or multiple sub-pixels emitting different colors, thereby the different colors are combined to emit the white light and/or the color light.

In the embodiment, each pixel 1000 comprises multiple sub-pixels, and the multiple sub-pixels can be implemented by a plurality of light-emitting units. In an embodiment, the plurality of light-emitting units comprises a first light-emitting unit P1, a second light-emitting unit P2, and a third light-emitting unit P3.

In an embodiment of the present application, each pixel 1000 comprises a light-emitting unit G emitting the green light, a light-emitting unit R emitting the red light, and a light-emitting unit B emitting the blue light. The first, second, third light-emitting units P1, P2, and P3 respectively correspond to the light-emitting unit G emitting the green light, the light-emitting unit R emitting the red light, and the light-emitting unit B emitting the blue light.

The pixels 1000 and/or the light-emitting units P1, P2, and P3 may be arranged in a matrix form. Here, the phrase that the pixels 1000 and/or the light-emitting units P1, P2, and P3 are arranged in the matrix form does not requires the pixels 1000 and/or the light-emitting units P1, P2, and P3 arranged exactly in rows or columns. The pixels 1000 and/or the light-emitting units P1, P2, and P3 also can be arranged along the directions of the rows or columns in positions like a “triangle” shape or a “L” shape.

As shown in FIG. 2, in accordance with an embodiment of the present application, the display device 101 includes a timing controller 350, a scan driver 310, a data driver 330, a scan line 130, a data line 120, and a pixel. When the pixel comprises the plurality of light-emitting units P1, P2, and P3, each light-emitting unit P1, P2, and P3 is individually connected to the scan driver 310 through the scan line 130 and connected to the data driver 330 through the data line 120.

The timing controller 350 receives various control signals and the image data required to drive the display device 101 illustrated in FIG. 1 from the outside (for example, a system for transmitting the image data), and then rearranges the received image data and transmits the image data to the data driver 330.

The scan driver 310 receives the scan control signal from the timing controller 350 and generates a scan signal in response thereto. The data driver 330 receives the data control signal and the image data from the timing controller 350 and generates a data signal in response thereto. The scan line 130 provides the scan signal generated from the scan driver 310 to the light-emitting units P1, P2, P3. The data signal generated from the data driver 330 is output to the data line 120. The data signal output to the data line 120 is input to the light-emitting units P1, P2, P3 selected by the scan signal.

When the light-emitting units P1, P2, P3 receive the scan signal from the scan line 130, they selectively emit light in response to the data signal input from the data line 120. The light-emitting unit P1, P2, P3 determines whether to emit light or not and the corresponding brightness in response to the received data signal. If the data signal corresponding to off is received, the light-emitting unit does not emit light and shows black.

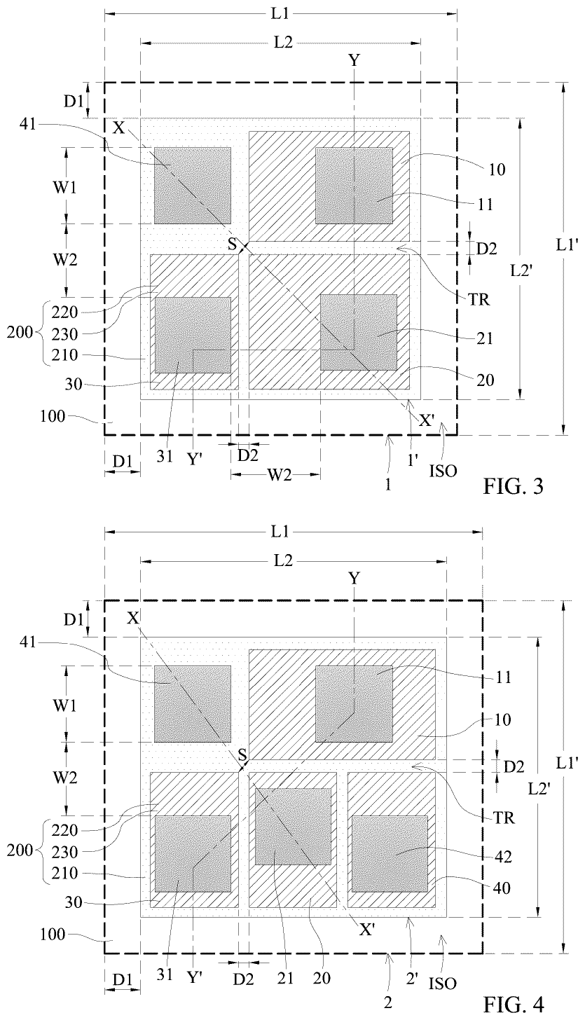

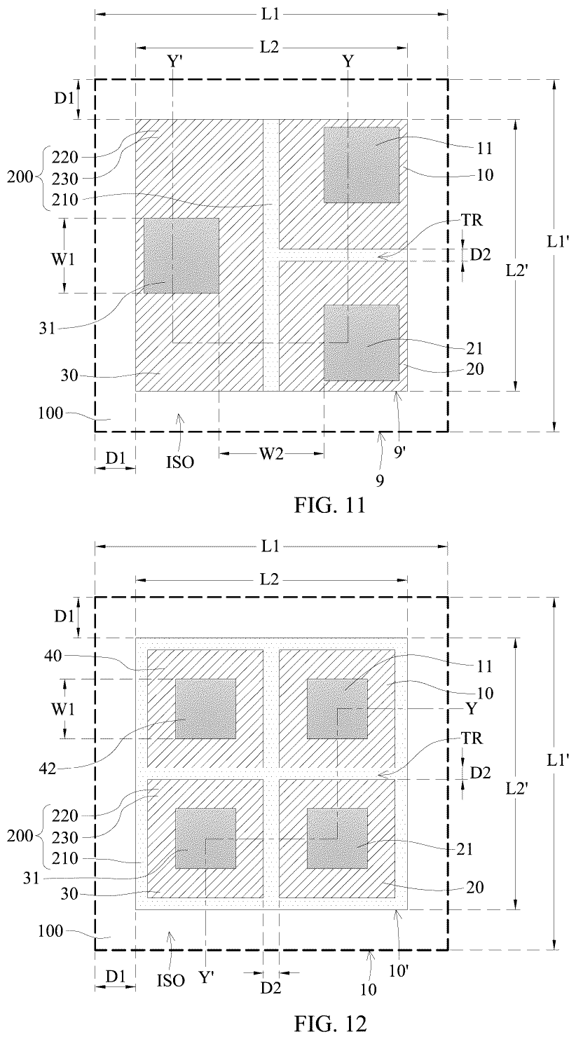

According to the embodiments disclosed in the application, the pixels 1000 illustrated in FIGS. 1 and 2 can be implemented by the monolithic array chip (MAC) 1′, 2′, 3′, 4′, 5′, 6′, 7′, 8′, 9′ or 10′ in FIGS. 3 to 12. The light-emitting units P1, P2, P3 can be implemented through the first light-emitting unit 10, the second light-emitting unit 20 and the third light-emitting unit 30 in FIGS. 3 to 12. In the embodiment of the application, the light-emitting devices 1, 2, 3, 4, 5, 6, 7, 8, 9 or 10, the monolithic array chip or the light-emitting unit may be the light-emitting diode (LED), resonant cavity light-emitting diode (RCLED), or laser diode (LD). The laser diode (LD) includes a vertical cavity surface emitting laser (VCSEL) or an edge emitting laser (EEL). In the following embodiments, the light-emitting diode will be illustrated as an example, and the others will not be described in detail again.

The chip size of the ordinary light-emitting diode (LED) is between 200 micrometers and 300 micrometers (μm), the chip size of the sub-millimeter light-emitting diode (mini LED) is approximately between 50 μm and 100 μm, and the micro LED is less than 50 μm. In the manufacturing process of the micro LED display, a plurality of light-emitting units with an epitaxial thickness of about 4-5 μm is formed on a wafer, it is called the chip on wafer (COW) stage. When the plurality of light-emitting units with the epitaxial thickness of about 4-5 μm is separated from a substrate which supports the micro LEDs by physical or chemical mechanism (lift-off), and then all or a part of the micro LEDs are directly or indirectly transferred to a temporary carrier substrate or the circuit substrate according to the user's needs, it is called the chip on carrier (COC). When the micro LEDs are transferred to a driving backplane having the circuit design, it is called chip on backplane (COB) stage. At present, a key production challenge of the micro LED is how to arrange a huge amount of micron-level light-emitting units on the target substrate or the circuit through the high-precision alignment apparatuses. This process is called mass transfer. Taking a 4K TV as an example, up to 24 million dies need to be transferred, and even if 10,000 dies are transferred at one time, it still needs to be repeated 2,400 times. In addition, limited by the process capability of the mass transfer, the spacing between the plurality of light-emitting units disposed on the carrier substrate before transfer must be also considered to avoid the inaccuracy during transfer due to the small spacing during the partial transfer of the light-emitting units, or not transferred due to the non-completely separation between the transferred light-emitting unit and the carrier substrate.

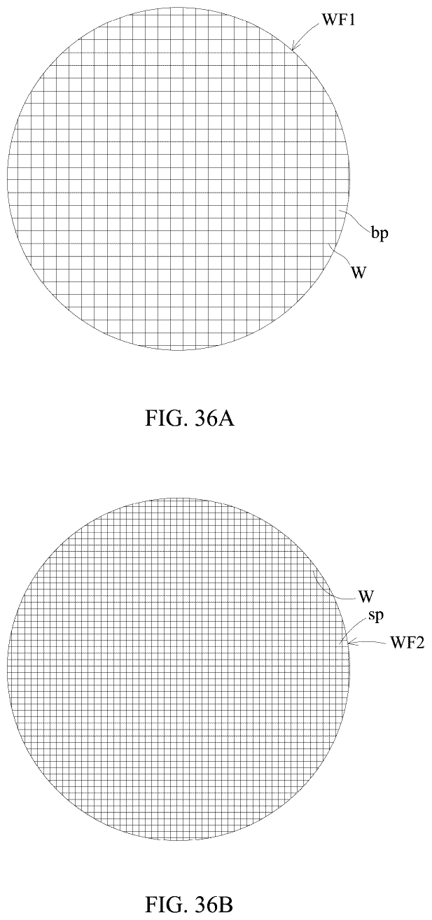

In the manufacturing process of the micro light-emitting diodes (micro LED), first, a semiconductor stack with a p-n junction is epitaxially grown on a substrate (e.g., a 4-inch, 6-inch or 8-inch wafer). The separation lane is defined to separate the patterned epitaxy of a plurality of light-emitting units through lithography and etching the semiconductor stack. After forming the n-type and p-type electrodes on the patterned epitaxy of the light-emitting unit, the substrate and the patterned epitaxial are separated by laser transfer or stamp transfer to form a plurality of light-emitting units. Limited by the ability of the transfer process, taking laser transfer as an example, in order to avoid affecting other adjacent light-emitting units when the laser irradiates on the target light-emitting unit, the width W of the separation lane around a single light-emitting unit is used as the calculation unit. The spacing (2 W) between two adjacent light-emitting units on the wafer is equivalent to 2 times of the width W of the separation lane to meet the transfer yield requirements. As shown in FIGS. 36A-36B, when the size of the light-emitting unit becomes smaller and smaller (the size of the light-emitting unit sp in FIG. 36B is smaller than the size of the light-emitting unit bp in FIG. 36A), under the same separation lane width W, the area occupied by the separation lanes on the wafer is increased (the area occupied by the separation lanes of wafer WF2 in FIG. 36B is larger than the area occupied by the separation lanes of wafer WF1 in FIG. 36A). This increases the epitaxy area removed by the separation lanes on the same wafer and results in a reduction of the epitaxy utilization.

Currently, the semiconductor stack with a thickness of approximately 10 μm or less can be processed through the semiconductor manufacturing processes to define the pattern of the light-emitting units. Multiple adjacent light-emitting units can be formed on the semiconductor stack through the semiconductor manufacturing processes such as lithography and etching. A small separation lane width can be defined between the light-emitting units, such as between 0.1 μm and 5 μm.

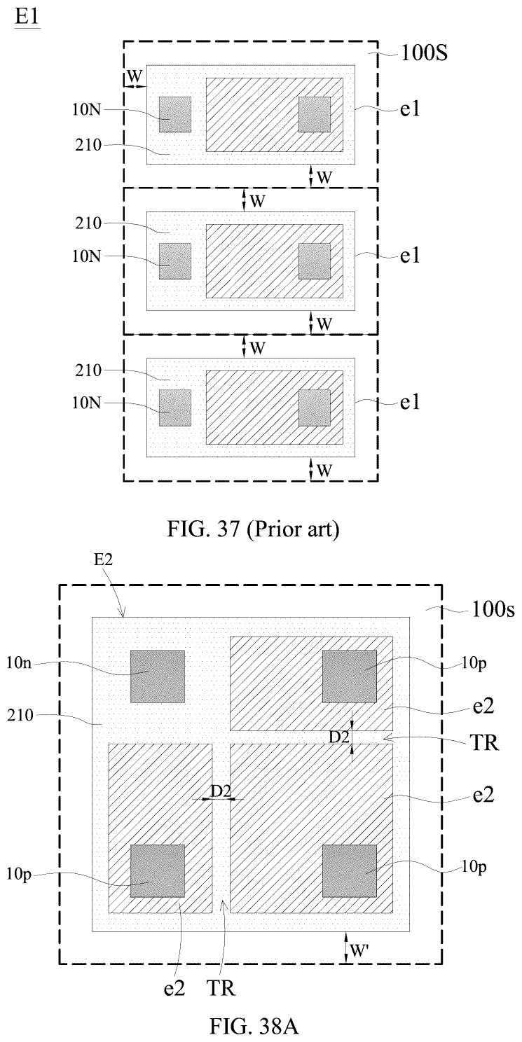

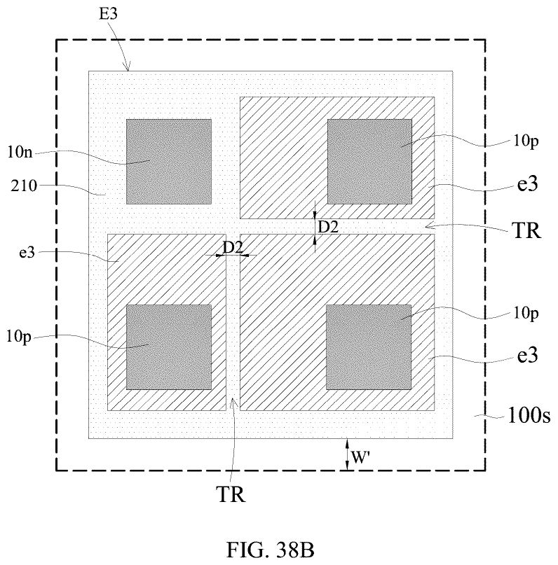

As shown in FIG. 37, the manufacturing method of the conventional light-emitting device E1 provided as a pixel comprises forming a light-emitting unit e1 with a length×width of 13 μm×28 μm on a wafer 100S, reserving a separation lane of width W (for example, 3 μm) around the light-emitting unit e1, and disposing three light-emitting units e1 on the substrate (not shown) of the display through a transfer process to form a pixel. The total area of the light-emitting device E1 occupied on wafer 100S is approximately 57 μm×34 μm (total area 1938 μm²). After deducting the spacing (2 times of the separation lane width W) between two of the three light-emitting units e1, the surrounding separation lane width W (e.g., 3 μm) around the three light-emitting units e1, and the luminescent area removed for forming the n-type electrodes 10N on each of the three light-emitting units e1, the total luminescent area of the light-emitting device E1 available for the light emission is approximately 510 μm². As shown in FIG. 38A, in accordance with an embodiment of the present application, a plurality of light-emitting units e2, such as three light-emitting units e2, are formed by defining the epitaxial stack on a wafer 100s through the lithography process. The three light-emitting units e2 are jointly formed on a first semiconductor layer 210. A p-type electrode 10p is formed on each of the light-emitting units e2 and a common n-type electrode 10n is formed on the first semiconductor layer 210 to form the light-emitting device E2. The light-emitting device E2 can serve as a pixel of the display. The light-emitting device E2 comprises a total area close to that of the conventional light-emitting device E1. For example, the light-emitting device E2 comprises a length×width of 44 μm×44 μm (total area 1936 μm²). The trench TR having the width D2 between the sub-pixels (light-emitting units e2) constituting the pixel (light-emitting device E2) can be formed through the lithography and etching process. Since the trench TR between two of the three light-emitting units e2 is formed by etching to remove a portion of the epitaxial stack to expose the first semiconductor layer 210, there is no need to consider the spacing limitation provided to separately transfer the three light-emitting units e2, and the three light-emitting units e2 are separately disposed on the first semiconductor layer 210 with a minimum distance. The conventional light-emitting device E1 is illustrated as a comparative example, the separation lane W of the light-emitting device E1 is provided based the consideration of the transfer process parameters, and the separation lane W is formed by etching to remove the epitaxial stack and expose the substrate. The width D2 of the trench TR between two adjacent light-emitting units e2 of the light-emitting device E2 is smaller than the spacing (2 times of the separation lane width W) between two adjacent light-emitting units e1 of the conventional light-emitting device E1. The light-emitting device E2 only reserves a separation lane W′ around the plurality of light-emitting units e2 for the transfer process. In other words, on a wafer (100S, 100s) of the same size, the total removal area of the light-emitting layer for forming the trench TR of the light-emitting device E2 can be smaller than the total removal area of the light-emitting layer for forming the separation lane W of the light-emitting device E1, thereby reducing the loss of light-emitting area and improving the epitaxial utilization rate of the wafer. When the light-emitting device E2 and the conventional light-emitting device E1 comprise a same or close total area (e.g., the total area difference is less than 0.2%), the total luminescent area of the light-emitting device E2 disclosed in FIG. 38A provided for light emission is approximately 1300 μm², which is 2.5 times of the total luminescent area of the conventional light-emitting device E1 shown in FIG. 37. When the light-emitting device E3 and the conventional light-emitting device E1 comprise a same or close total luminescent area (e.g., the total area difference is less than 0.2%), the light-emitting area of the light-emitting device E3 in FIG. 38B being removed to form the separation lane and sacrificed to form the n-electrode is reduced. Therefore, when the light-emitting device E3 and the conventional light-emitting device E1 shown in the FIG. 37 comprise a same (e.g., 510 μm²) or close total luminescent area (e.g., the total area difference is less than 0.2%), the total area of the light-emitting device E3 is smaller than that of the light-emitting device E1, the epitaxial utilization rate of the wafer is improved, and the output quantity of light-emitting devices on the wafer is increased. In addition, by forming the three light-emitting units e2 or e3 on the first semiconductor layer 210 to form the light-emitting device E2 or the light-emitting device E3, the transfer times of the mass transfer can be reduced, and thereby reducing the defects during the transfer process.

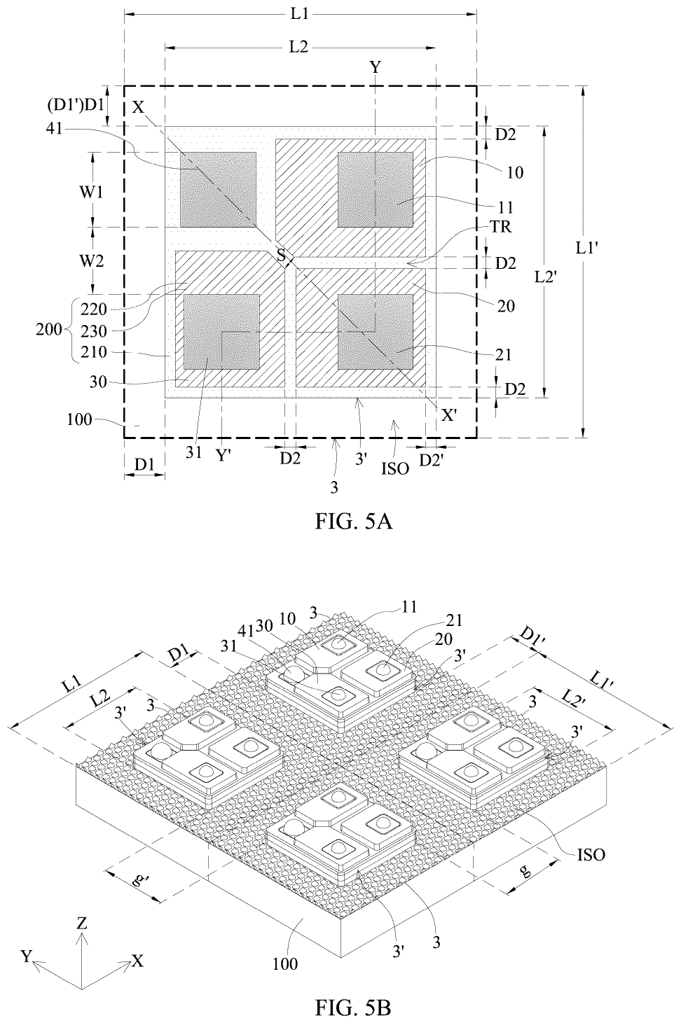

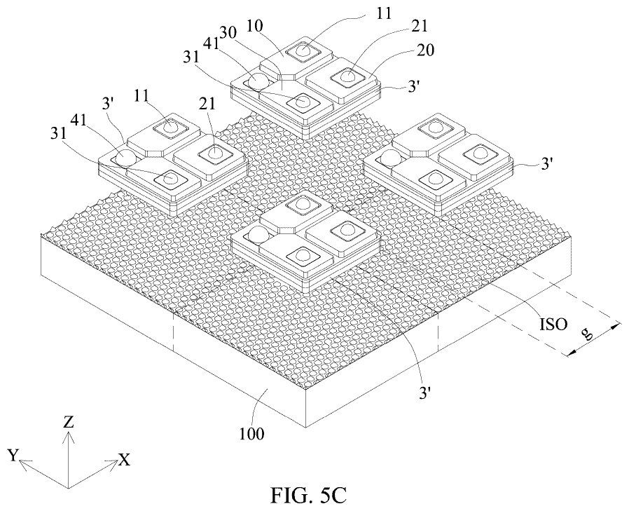

According to the first embodiment of the present disclosure, FIGS. 3 to 5A and FIGS. 6A to 12 illustrate the formation of a plurality of monolithic array chips 1′, 2′, 3′, 4′, 4B′, 5′, 6′, 7′, 8′, 9′, 10′ on a substrate 100. Although FIGS. 3-5A and FIGS. 6A-12 only illustrate one monolithic array chip, the embodiment of forming a plurality of monolithic array chips 1′, 2′, 3′, 4′, 5′, 6′, 7′, 8′, 9′, or 10′ on the substrate 100 through photolithography can be referred to FIG. 5B.

As shown in FIGS. 3 to 12, the monolithic array chip 1′, 2′, 3′, 4′, 4B′, 5′, 6′, 7′, 8′, 9′, or 10′, and the separation lane ISO partial exposing substrate 100 and surrounding thereof form a light-emitting device 1, 2, 3, 4, 4B, 5, 6, 7, 8, 9 or 10. Subsequently, the plurality of monolithic array chips 1′, 2′, 3′, 4′, 4B′, 5′, 6′, 7′, 8′, 9′, 10′ and the substrate 100 are separated according to the needs of the user or the application. Finally, the plurality of monolithic array chips 1′, 2′, 3′, 4′, 4B′, 5′, 6′, 7′, 8′, 9′, 10′ is separated to form independent chips and then be transferred onto the temporary carrier substrate or the driving backplane having the circuit design. To simplify the description, one light-emitting device and one monolithic array chip on the substrate 100 will be described below. As shown in FIGS. 3 to 12, each of the light-emitting devices 1, 2, 3, 4, 4B, 5, 6, 7, 8, 9, 10 comprises a monolithic array chip 1′, 2′, 3′, 4′, 4B′, 5′, 6′, 7′, 8′, 9′, 10′ on the substrate 100. Each of the light-emitting devices includes a plurality of light-emitting units. For example, any one of the plurality of light-emitting devices 1, 2, 3, 4, 4B, 5, 6, 7, 8, 9, 10 includes a first light-emitting unit 10, a second light-emitting unit 20, and a third light-emitting unit 30 jointly formed on the same semiconductor layer to form the monolithic array chip (MAC) 1′, 2′, 3′, 4′, 4B′, 5′, 6′, 7′ and 8′. In other words, the monolithic array chip is composed of the plurality of light-emitting units. The monolithic array chip includes multiple LED structures arranged in an array in one single body. The detailed structures will be described in detail later. Here, the phrase of the “array” encompasses intentionally separating the multiple LED structures, and the multiple LED structures are arranged regularly or irregularly to form a matrix, such as 3×1, 1×3 or 2×2. In the disclosure, the monolithic array chip 1′, 2′, 3′, 4′, 4B′, 5′, 6′, 7′, 8′, 9′, 10′ includes the plurality of light-emitting units (LED structures) 10, 20, 30 disposed on a semiconductor layer. A high-density integrated light-emitting unit array is formed on the same semiconductor layer through the chip process (semiconductor process). The array arrangement form of the multiple light-emitting units, the number of the light-emitting units in the monolithic array chip, and the area size of each light-emitting unit can be determined according to the needs of the user or the application.

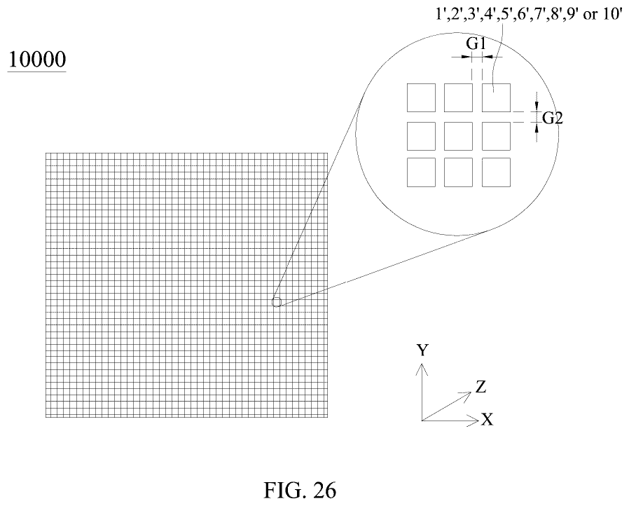

As shown in FIG. 26, in the display application, the monolithic array chip 1′, 2′, 3′, 4′, 4B′, 5′, 6′, 7′, 8′, 9′, 10′ is provided as an individual pixel, and the plurality of light-emitting units 10, 20, 30 of the monolithic array chip 1′, 2′, 3′, 4′, 4B′, 5′, 6′, 7′, 8′, 9′, 10′ is respectively provided as a sub-pixel. The light-emitting module 10000 is composed of the plurality of monolithic array chips 1′, 2′, 3′, 4′, 4B′, 5′, 6′, 7′, 8′, 9′, 10′. In the embodiment, the monolithic array chip 1′, 2′, 3′, 4′, 4B′, 5′, 6′, 7′, 8′, 9′, 10′ can serve as a pixel package to be connected to the circuit board or thin-film transistor (TFT), and then the light-emitting module 10000 is provided. As the pixel package, a periphery of the monolithic array chip 1′, 2′, 3′, 4′, 4B′, 5′, 6′, 7′ or 8′ can be filled by the black matrix (BM) material and leave only an upper surface of the light-emitting units 10, 20, 30 to serve as a light-emitting surface. Compared with the widely used liquid crystal display (LCD) technology, the light-emitting module 10000 provides better contrast, response time, and energy efficiency. Compared with the traditional display pixels composed of three independent R, G, and B micro LEDs, the light-emitting module 10000 composed of the monolithic array chips 1′, 2′, 3′, 4′, 4B′, 5′, 6′, 7′, 8′, 9′, 10′ can provide greater process freedom for users to choose.

In a manufacturing process, the wafer includes the plurality of monolithic array chips according to the disclosure, and there is a spacing between two adjacent monolithic array chips. For the convenience of explanation, the monolithic array chip and the separation lane exposing a portion of the substrate 100 which surrounds a periphery of the monolithic array chip is illustrated as a light-emitting device structure in the following embodiment, it can be understood that the spacing between any two adjacent monolithic array chips is twice the width of the separation lane which is not otherwise specified here. FIGS. 3 to 9 respectively illustrates the top views of the monolithic array chips 1′, 2′, 3′, 4′, 4B′, 5′, 6′, 7′ having the flip-chip electrode in the first to the seventh embodiments. FIGS. 10 to 12 respectively illustrates the top views of the monolithic array chips 8′, 9′, 10′ having the vertical electrode in the eighth embodiment to the tenth embodiment. The monolithic array chips 1′, 2′, 3′, 4′, 4B′, 5′, 6′, 7′, 8′, 9′, 10′ in FIGS. 3 to 12 respectively includes but is not limited to three light-emitting units, for example, the first light-emitting unit 10, the second light-emitting unit 20 and the third light-emitting unit 30. Each of the three light-emitting units 10, 20, 30 is configured to emit the light of the same (peak) wavelength. In some embodiments, each of the light-emitting units 10, 20, 30 is configured to emit the light with a peak wavelength λ that is at least 380 nanometers (nm) and/or no greater than 490 nanometers. In some embodiments, each of the light-emitting units 10, 20, 30 is configured to emit the deep ultraviolet light (UVC) having a peak wavelength λ in a wavelength range of 100 nm to 280 nm. In some embodiments, the light-emitting units 10, 20, and 30 have different peak wavelengths under different driving current densities.

The size of the light-emitting device 1, 2, 3, 4, 4B, 5, 6, 7, 8, 9, 10 and the monolithic array chip 1′, 2′, 3′, 4′, 4B′, 5′, 6′, 7′, 8′, 9′, 10′ can be determined according to the needs of the user or the application. In some embodiments, the light-emitting device 1, 2, 3, 4, 4B, 5, 6, 7, 8, 9, 10 includes a size not greater than 10000 μm², 7500 μm², 5000 μm² or 2500 μm², such as less than or equal to 1600 μm², less than or equal to 900 μm², or less than or equal to 400 μm². In some embodiments, the monolithic array chips 1′, 2′, 3′, 4′, 4B′, 5′, 6′, 7′, 8′, 9′, 10′ located on the same semiconductor layer includes a size not greater than 10000 μm², 7500 μm², 5000 μm² or 2500 μm², such as less than or equal to 1600 μm², less than or equal to 900 μm², or less than or equal to 400 μm². In some embodiments, the top view area of each of the light-emitting units 10, 20, 30 located on the same semiconductor layer (for example, the first semiconductor layer 210 in FIGS. 3 to 12) can be defined as including an area not larger than the following areas: 8100 μm², 6400 μm², 4900 μm², 3600 μm², 2500 μm², 1600 μm², 900 μm², 400 μm², 100 μm² or 25 μm².

In some embodiments, as shown in FIGS. 3 to 12, the light-emitting device 1, 2, 3, 4, 4B, 5, 6, 7, 8 includes one side having a length L1 not greater than 100 μm, 85 μm, 70 μm, 60 μm, 50 μm or not greater than 40 μm, and/or other side having a length L1′ not greater than 100 μm, 85 μm, 70 μm, 60 μm, 50 μm or not greater than 40 μm. In some embodiments, the light-emitting device 1, 2, 3, 4, 4B, 5, 6, 7, 8, 9, 10 includes a rectangle, and a ratio between the length L1 of the one side of the light-emitting device 1, 2, 3, 4, 4B, 5, 6, 7, 8, 9, 10 and the length L1′ of the other side is between 0.3-1.8 or between 0.5-1.5. In some embodiments, the light-emitting device 1, 2, 3, 4, 4B, 5, 6, 7, 8, 9, 10 includes a square, and a ratio between the length L1 of the one side of the light-emitting device 1, 2, 3, 4, 4B, 5, 6, 7, 8, 9, 10 and the length of the other side L1′ is between 0.9-1.1 or is 1.

In some embodiments, as shown in FIGS. 3 to 12, the light-emitting area of the monolithic array chips 1′, 2′, 3′, 4′, 4B′, 5′, 6′, 7′, 8′, 9′, 10′ (the top view area of the semiconductor stack 200 surrounded by the separation lanes ISO in FIGS. 3 to 12) includes one side having a length L2 not greater than 90 μm, 75 μm, 60 μm, 50 μm, 40 μm or not greater than 30 μm, and/or other side having a length L2′ not greater than 90 μm, 75 μm, 60 μm, 50 μm, 40 μm or not greater than 30 μm. In some embodiments, the monolithic array chip 1′, 2′, 3′, 4′, 4B′, 5′, 6′, 7′, 8′, 9′, 10′ includes a rectangular shape, the ratio between the length L2 of the one side and the length L2′ of the other side of the monolithic array chip 1′, 2′, 3 ‘, 4’, 4B′, 5′, 6′, 7′, 8′, 9′, 10′ is between 0.3-1.8 or between 0.5-1.5. In some embodiments, the monolithic array chip 1′, 2′, 3′, 4′, 4B′, 5′, 6′, 7′, 8′, 9′, 10′ includes a square, a ratio between the length L2 of the one side and the length L2′ of the other side of the monolithic array chip 1′, 2′, 3 ‘, 4’, 4B′, 5′, 6′, 7′, 8′, 9′, 10′ is between 0.9-1.1 or is 1.

In some embodiments, as shown in FIGS. 3 to 12, a ratio between two connected sides of the light-emitting units 10, 20, and 30 of each of the monolithic array chips 1′, 2′, 3′, 4′, 4B′, 5′, 6′, 7′, 8′, 9′, 10′ is between 0.4-2.5 or between 0.5-2.2.

In some embodiments, a ratio between the two connected sides of each of the light-emitting units 10, 20, 30 is between 0.5-2.5, and the ratio between the two connected sides of the light-emitting units 10, 20, 30 are different.

In some embodiments, a ratio between the two connected sides of each of the light-emitting units 10, 20, 30 is between 0.5-2.5, and the ratios between the two connected sides of the light-emitting unit 10, 20, 30 are the same.

In some embodiments, a ratio between the two connected sides of each light-emitting unit 10, 20, 30 is between 0.5-2.5, the ratios between the two connected sides of the light-emitting units 10 and 30 are the same, and the ratio between the two connected sides of the light-emitting unit 20 is different from the ratio between the two connected sides of the light-emitting unit 10 or 30.

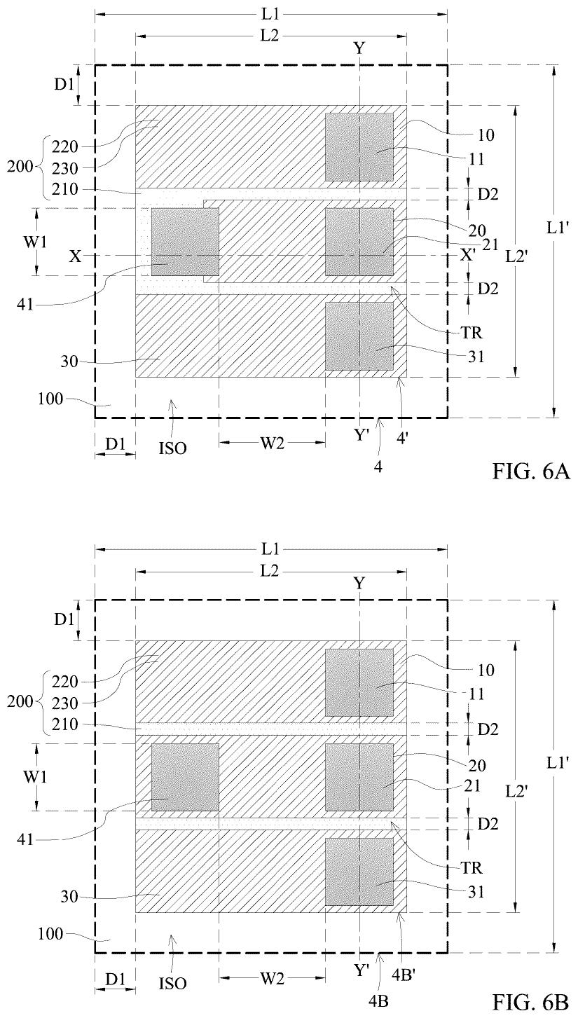

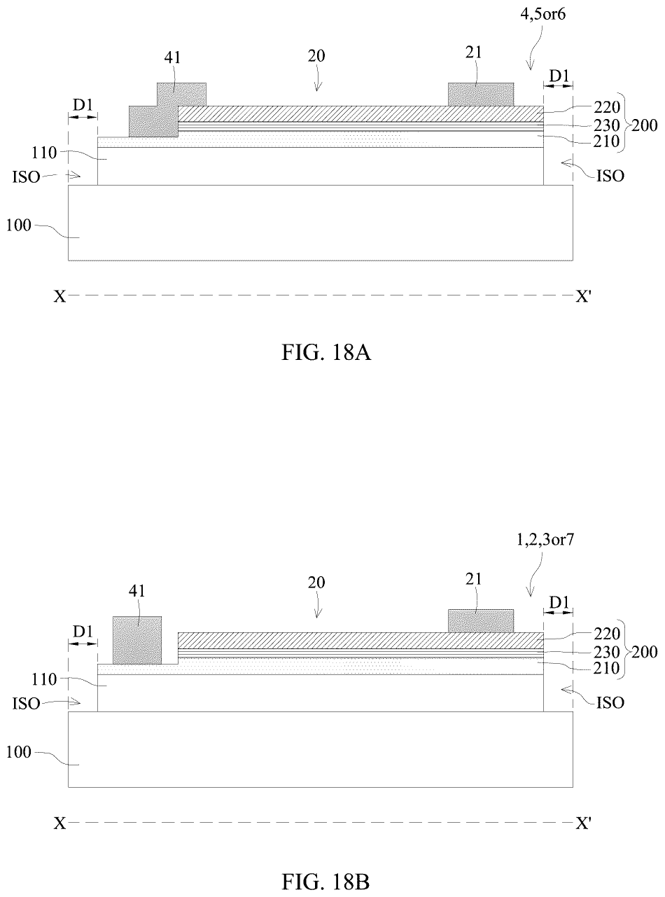

In an embodiment, as shown in FIGS. 3-12, the monolithic array chip 1′, 2′, 3′, 4′, 4B′, 5′, 6′, 7′, 8′, 9′, 10′ includes a first semiconductor layer 210, a common electrode 41 located on the first semiconductor layer 210 (not shown in FIGS. 10 to 12), the first light-emitting unit 10 with a first electrode 11 located on the first semiconductor layer 210, the second light-emitting unit 20 with a second electrode 21 located on the first semiconductor layer 210, the third light-emitting unit 30 with a third electrode 31 located on the first semiconductor layer 210, wherein the first light-emitting unit 10, the second light-emitting unit 20 and the third light-emitting unit 30 are separated from each other by a trench TR. In order to provide the high-resolution LED array, such as the micro-LED array, compared with the light-emitting surface area of the traditional LED, the light-emitting surface area of each light-emitting unit 10, 20, 30 of the monolithic array chip 1′, 2′, 3′, 4′, 4B′, 5′, 6′, 7′, 8′, 9′ or 10′ is smaller. The trench TR between the light-emitting units 10, 20, 30 includes a minimum width D2 less than 20 μm, 10 μm, or 5 μm (e.g., less than or equal to 1 μm) to provide the higher resolution array. Specifically, the trench TR includes a minimum width D2 between 0.01 μm-20 μm, between 0.1 μm-10 μm, between 0.2 μm-9 μm, between 0.3 μm-8 μm, and between 4 μm-7 μm, between 0.5 μm-6 μm, between 0.5 μm-5 μm, between 0.4 μm-4 μm, between 0.3 μm-3 μm, between 0.2 μm-2 μm, or between 0.1 μm-1 μm. In some embodiments, referring to FIG. 18A (the cross-sectional view along the line X-X′ in FIGS. 6A and 7-8) and FIG. 18B (the cross-sectional view along the line X-X′ in FIGS. 3-5A and 9), the chip on wafer (COW) stage is defined as when the plurality of monolithic array chips 1′, 2′, 3′, 4′, 4B′, 5′, 6′, 7′ are not separated from the substrate 100, and the monolithic array chip 1′, 2′, 3′, 4′, 4B′, 5′, 6′, 7′ may include an undoped semiconductor layer 110 located between the substrate 100 and the first semiconductor layer 210.

In an embodiment, as shown in FIG. 5A, the first light-emitting unit 10, the second light-emitting unit 20, and the third light-emitting unit 30 are separated from each other by the trench TR. A distance D2′ between the first light-emitting unit 10, the second light-emitting unit 20, the third light-emitting unit 30 and one side of the first semiconductor layer 210 is less than the minimum width D2 of the trench TR. In an embodiment, the distance D2′ is 0.5 μm-1.5 μm.

In an embodiment, as shown in FIGS. 6A-8, the first light-emitting unit 10, the second light-emitting unit 20, and the third light-emitting unit 30 are separated from each other by the trenches TR. The first light-emitting unit 10, the second light-emitting unit 20, and the third light-emitting unit 30 include a side that overlaps with one side of the first semiconductor layer 210 in a top view or being flush with one side of the first semiconductor layer 210 in a side view (not shown). That is, the distance between the side of the first light-emitting unit 10, the second light-emitting unit 20, and the third light-emitting unit 30 and the one side of the first semiconductor layer 210 is equal to zero.

In the wafer, a spacing between any two adjacent monolithic array chips 1′, 2′, 3′, 4′, 4B′, 5′, 6′, 7′, 8′, 9′, 10′, such as the spacing g in FIG. 5B, is provided to transfer the multiple monolithic array chips 1′, 2′, 3′, 4′, 4B′, 5′, 6′, 7 ‘, 8’, 9′ or 10′ onto a temporary carrier substrate or a driving backplane having the circuit design, which can be defined as the chip on carrier (COC) or chip on backplane (COB) stage. The yield of the transfer process can be improved by adjusting the spacing, or the spacing can be adjusted according to the user's requirements for the pixel pitch on the display backplane. The separation lane ISO is located on the periphery of the monolithic array chip 1′, 2′, 3′, 4′, 4B′, 5′, 6′, 7′, 8′, 9′, 10′ to expose an upper surface of the substrate 100. A width of the spacing between any two adjacent monolithic array chips 1′, 2′, 3′, 4′, 4B′, 5′, 6′, 7′, 8′, 9′, 10′ on the wafer is two times the width of the separation lane ISO of the light-emitting device 1, 2, 3, 4, 4B, 5, 6, 7, 8, 9, 10. In an embodiment, the width of the separation lane ISO is 1.5 μm-3 μm, 2.5 μm-10 μm, or 2 μm-5 μm. In other words, the width of the spacing is 5 μm-20 μm, 3 μm-9 μm, or 4 μm-10 μm. For the convenience of description, FIGS. 3-12 illustrate only one light-emitting device 1, 2, 3, 4, 4B, 5, 6, 7, 8, 9, 10. As shown in FIGS. 3-12, the separation lane ISO surrounds the first semiconductor layer 210 of the monolithic array chip 1′, 2′, 3′, 4′, 4B′, 5′, 6′, 7′, 8′, 9′, 10′, wherein the separation lane ISO includes a width D1 (or D1′) between 1.5 μm-3 μm, 2.5 μm-10 μm, or 2 μm-5 μm. The minimum width D2 of the trench TR is smaller than the width D1 (or D1′) of the separation lane ISO. In an embodiment, the ratio between the minimum width D2 of the trench TR and the width D1 (or D1′) of the separation lane ISO is less than 0.5. In an embodiment, the shape of the above-mentioned monolithic array chip is a rectangle including the first side, the second side, the third side, and the fourth side, where the first side and the third side are opposite sides, and the second side and the fourth side are opposite sides, the width of the separation lane ISO adjacent to the first side, the third side is different from the width of the separation lane ISO adjacent to the second side, the fourth side.

In an embodiment, the first light-emitting unit 10, the second light-emitting unit 20 and the third light-emitting unit 30 each includes an active layer 230 and a second semiconductor layer 220 located on the first semiconductor layer 210, wherein the active layer 230 is located between the first semiconductor layer 210 and the second semiconductor layer 220.

In an embodiment, the semiconductor layer (such as the undoped semiconductor layer 110 shown in FIG. 15) is located between the first semiconductor layer 210 and the substrate 100. The first semiconductor layer 210, the active layer 230 and the second semiconductor layer 220 on the separation lane ISO can be removed to expose the undoped semiconductor layer 110. The undoped semiconductor layer 110 on the separation lane ISO continuously or discontinuously exposes to surround the semiconductor stack 200, and the minimum width D2 of the trench TR is smaller than the width D1 of the separation lane ISO. In an embodiment, during the subsequent chip processing, the undoped semiconductor layer 110 can be selectively removed after removing the substrate 100.

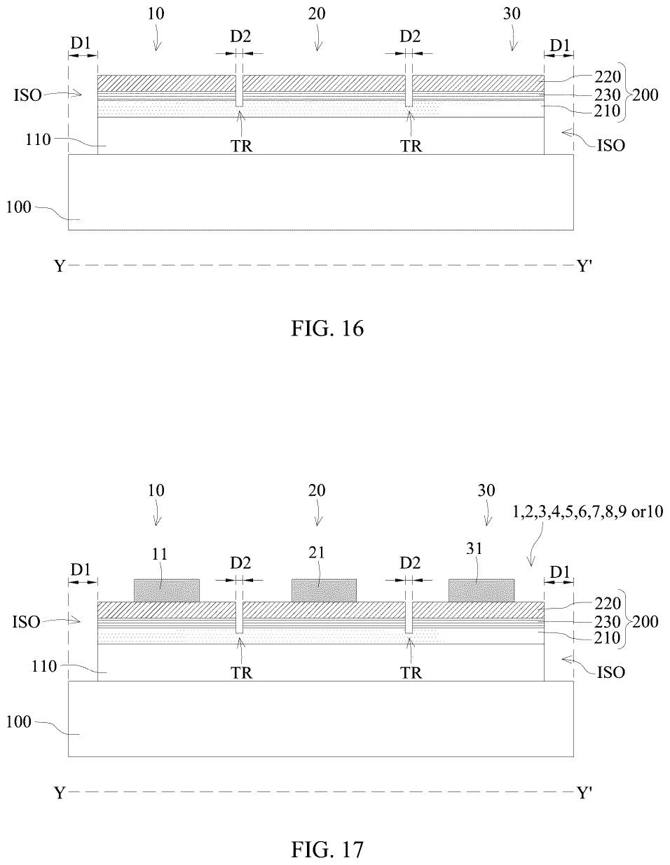

In an embodiment, as shown in FIG. 16 or FIGS. 17-18B, the undoped semiconductor layer 110, the first semiconductor layer 210, the active layer 230 and the second semiconductor layer 220 on the separation lane ISO can be removed to expose the substrate 100. The surface of the substrate 100 exposed on the separation lane ISO surrounds the semiconductor stack 200, and the minimum width D2 of the trench TR is smaller than the width D1 of the separation lane ISO. In an embodiment, during the subsequent chip processing, the undoped semiconductor layer 110 can be selectively removed after removing the substrate 100.

In an embodiment, the monolithic array chip 1′, 2′, 3′, 4′, 4B′, 5′, 6′, 7′, 8′, 9′, 10′ includes the plurality of light-emitting units, and the light-emitting units include the same or different top view areas. As shown in FIG. 3, the first light-emitting unit 10, the second light-emitting unit 20 and the third light-emitting unit 30 of the monolithic array chip 1′ include different top view areas. In an embodiment, the light-emitting units include the same or different shapes. For example, the shape of the light-emitting unit includes a triangle, a rectangle, or a polygon such as a pentagon or a hexagon.

In an embodiment, as shown in FIG. 3, the first light-emitting unit 10 and the third light-emitting unit 30 each includes a top-view area that is smaller than the top-view area of the second light-emitting unit 20. The second light-emitting unit 20 and the common electrode 41 are located on one diagonal line on the monolithic array chip 1′, and the first light-emitting unit 10 and the third light-emitting unit 30 are located on the other diagonal line on the monolithic array chip 1′.

In an embodiment, as shown in FIG. 4 and FIG. 12, the monolithic array chip 2′, 10′ further includes one or more light-emitting units 40 which can be used as backup light-emitting areas, and one or more electrodes 42 respectively located on the light-emitting units 40. A first wavelength conversion layer, a second wavelength conversion layer, or no wavelength conversion layer can be provided on the light-emitting unit 40 to be used as a backup light-emitting area for the red light, the green light, or the blue light.

In an embodiment, as shown in FIG. 5A, the top view area of the first light-emitting unit 10 and/or the third light-emitting unit 30 is larger than the top view area of the second light-emitting unit 20. The first light-emitting unit 10 and the third light-emitting unit 30 are located on a diagonal line of the monolithic array chip 3′. In an embodiment (not shown), the top view area of the second light emitting unit 20 is larger than the top view area of the first light emitting unit 10 and/or the third light emitting unit 30, and/or the top view area of the first light emitting unit 10 is larger than the top view area of the third light emitting unit 30. Considering the yield of the manufacturing process, the first light-emitting unit 10 and the third light-emitting unit 30 each includes a fifth side parallel to each other to prevent the two light-emitting units from being too close at opposite corners, which may cause manufacturing difficulties. A distance S between the fifth side of the first light-emitting unit 10 and the fifth side of the third light-emitting unit 30 is greater than the minimum width D2 of the trench TR. In an embodiment, the distance

$$S = \sqrt[2]{D {2}^{2} + D {2}^{2}} .$$

In some embodiments, when the first light-emitting unit 10, the second light-emitting unit 20 and the third light-emitting unit 30 are sequentially arranged along the three corners of the monolithic array chip 1′, 2′ or 3′, the first electrode 11, the second electrode 21, and the third electrode 31 are respectively arranged adjacent to the three corners, and the common electrode 41 is formed near the fourth corner. The second semiconductor layer 220 and the active layer 230 near the fourth corner can be removed to expose the semiconductor layer 210, and the common electrode 41 can be formed thereon.

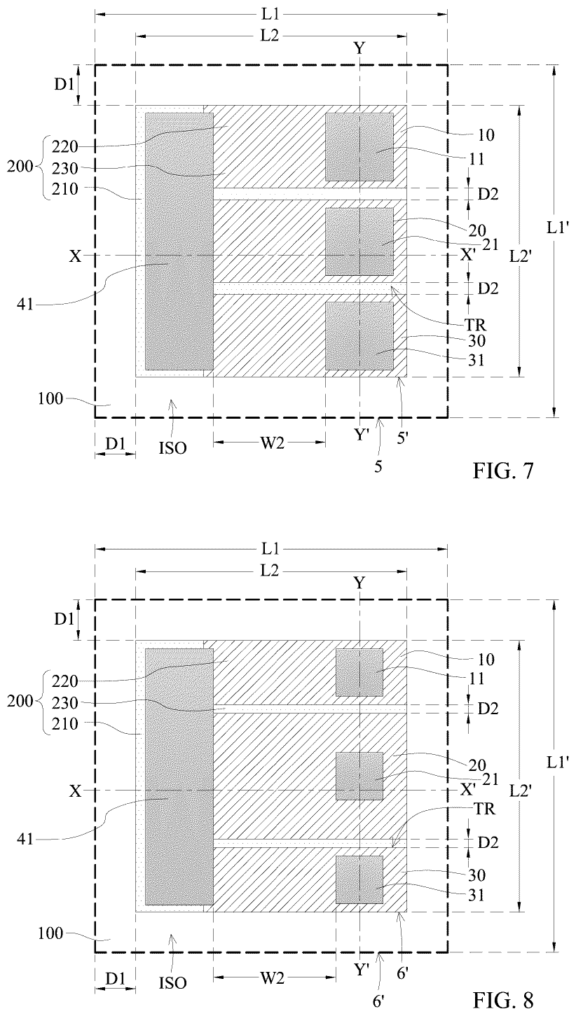

In an embodiment, as shown in FIGS. 6A, 6B and 7, the first light-emitting unit 10, the second light-emitting unit 20 and the third light-emitting unit 30 are arranged in 1×3 array or 3×1 array. The difference between the embodiments in FIGS. 6A, 6B and 7 is that the common electrode 41 can be formed on the exposed first semiconductor layer 210 and covers one or all of the first light-emitting unit 10, the second light-emitting unit 20 and the third light-emitting unit 30.

As shown in FIG. 6A, the light-emitting unit (e.g., the second light-emitting unit 20) covered by the common electrode 41 includes an area smaller than that of the light-emitting unit 10, 30 not covered by the common electrode 41. In order to increase the light-emitting area of the monolithic array chip 4′, any two light-emitting units of the first light-emitting unit 10, the second light-emitting unit 20 and the third light-emitting unit 30 (for example, the first light-emitting unit 10 and the third light-emitting unit 30) comprises the same top view area (e.g., the luminous top view area). As shown in FIG. 6A, when the first light-emitting unit 10 and the third light-emitting unit 30 each includes a top-view area larger than the top-view area of the second light-emitting unit 20, the common electrode 41 and the light-emitting unit (for example, the second light-emitting unit 20) having a smaller top-view area are placed in the same column. The common electrode 41 is formed on the partially exposed first semiconductor layer 210 and partially covers the second light emitting unit 20. As shown in FIG. 6B, the common electrode 41 may be formed on one of the first light-emitting unit 10, the second light-emitting unit 20 and the third light-emitting unit 30. Compared with the second light-emitting unit 20 illustrated in FIG. 6A, the second light-emitting unit 20 illustrated in FIG. 6B has a larger light-emitting area. The embodiment illustrated in FIG. 6B is to remove a part of the semiconductor stack 200 of the second light-emitting unit 20 to form a through hole (not shown) and expose the first semiconductor layer 210. The common electrode 41 is formed on the through hole (not shown) and covers the second light-emitting unit 20.

As shown in FIG. 7, the first light-emitting unit 10, the second light-emitting unit 20 and the third light-emitting unit 30 include the same top view area. The common electrode 41 may cover the first light-emitting unit 10, the second light-emitting unit 20, and the third light-emitting unit 30 at the same time. In an embodiment, the common electrode 41 covers any two or all of the first light-emitting unit 10, the second light-emitting unit 20 and the third light-emitting unit 30. The common electrode 41 can be separated from the first light-emitting unit 10 and the second semiconductor layer 220 and the active layer 230 of the second light-emitting unit 20 by an insulating layer to avoid the electrical problems of the device.

In an embodiment, as shown in FIG. 6A, when the top view area of the second light-emitting unit 20 is smaller than the top view area of the first light-emitting unit 10 and/or is smaller than the top view area of the third light-emitting unit 30, a ratio between the top view area of the first light-emitting unit 10 or the third light-emitting unit 30 and the top view area of the second light-emitting unit 20 is between 1.3-1.7.

In an embodiment, as shown in FIG. 7, the top view areas of any two of the first light-emitting unit 10, the second light-emitting unit 20 and the third light-emitting unit 30 have a ratio between 0.9-1.1.

In an embodiment, as shown in FIGS. 3 and 8, one light-emitting unit of the first light-emitting unit 10, the second light-emitting unit 20 and the third light-emitting unit 30 includes a top view area larger than the top view area of the other light-emitting units. For example, the second light-emitting unit 20 has a top view area larger than the top view areas of the first light-emitting unit 10 or the third light-emitting unit 30. In an embodiment, as shown in FIG. 3, the first light-emitting unit 10 and the third light-emitting unit 30 include the same or different top-view areas, and the top-view area of the second light-emitting unit 20 is larger than that of the first light-emitting unit 10 and the third light-emitting unit 30. For example, the first light-emitting unit 10 and the third light-emitting unit 30 each includes a top-view area of 8×14 μm², and the second light-emitting unit 20 includes a top-view area of 12×12 μm². For example, the first light-emitting unit 10 and the third light-emitting unit 30 each includes a top-view area of 6×10 μm², and the second light-emitting unit 20 includes a top-view area of 8×8 μm².

In an embodiment, as shown in FIG. 3, when the second light-emitting unit 20 includes a top view area larger than the top view area of the first light-emitting unit 10 or larger than the top view area of the third light-emitting unit 30, the ratio between the top view area of the second light-emitting unit 20 and the top view area of each of the first light-emitting unit 10 and the third light-emitting unit 30 is 1.7-2.3 or 1.01-1.69.

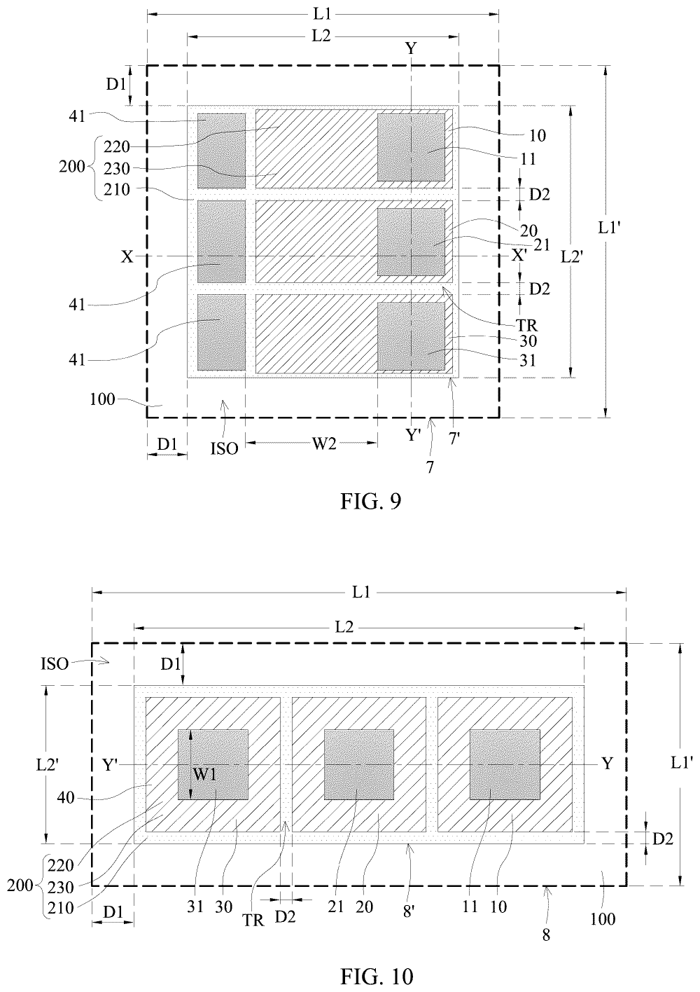

In an embodiment, as shown in FIG. 9, the first light-emitting unit 10, the second light-emitting unit 20 and the third light-emitting unit 30 are arranged in a 1×3 or 3×1 array. The first light-emitting unit 10, the second light-emitting unit 20 and the third light-emitting unit 30 include the same top-view area. The light-emitting device 7 includes a plurality of common electrodes 41 which is arranged one-to-one with the first light-emitting unit 10, the second light-emitting unit 20 and the third light-emitting unit 30 respectively. By arranging the plurality of common electrodes 41 to respectively inject the external current into the first light-emitting unit 10, the second light-emitting unit 20 and the third light-emitting unit 30, the current distribution of each light-emitting unit during operation is more uniform and a more consistent operation photoelectric characteristics is provided.

Referring to FIGS. 3-5A, FIGS. 6A-9 and FIGS. 17-18B, the common electrode 41, the first electrode 11, the second electrode 21 and the third electrode 31 are located on the same side of the semiconductor stack 200 to form a flip-chip electrode structure. In the embodiment, the common electrode 41, the first electrode 11, the second electrode 21 and the third electrode 31 include metal reflective materials, such as silver (Ag), chromium (Cr), nickel (Ni), titanium (Ti), aluminum (Al), rhodium (Rh), ruthenium (Ru) or a combination of the above materials.

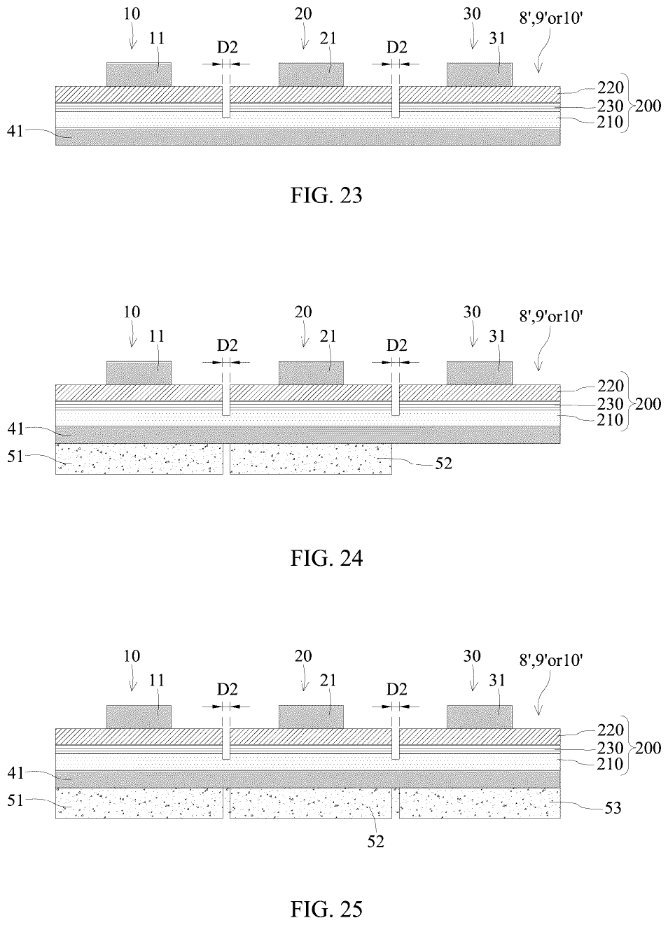

Referring to FIGS. 10-12 and FIGS. 23-25, FIGS. 10-12 illustrate the top view of the light-emitting devices 8, 9, 10 after forming the first electrode 11, the second electrode 21 and the third electrode 31, and before removing the substrate 100 and forming the common electrode 41. FIGS. 23-25 illustrate the cross-sectional views of the monolithic array chip 8′, 9′, 10′ with vertical electrodes after removing the substrate 100 and the undoped semiconductor layer 110, and forming the common electrode 41 on the side opposite to the side of the semiconductor stack 200 where the first electrode 11, the second electrode 21 and the third electrode 31 are located. For the convenience of description, the structures in FIGS. 10-12 before removing the substrate 100, the undoped semiconductor layer 110 and forming the common electrode 41 are still referred to as the monolithic array chips 8′, 9′, 10′. Since the common electrode 41 is located on the light-emitting surface of the monolithic array chip 8′, 9′, 10′, the common electrode 41 includes a transparent conductive material, such as indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgxO, 0≤x≤1). In the embodiment, the first electrode 11, the second electrode 21 and the third electrode 31 include metal reflective materials, such as silver (Ag), chromium (Cr), nickel (Ni), titanium (Ti), aluminum (Al), rhodium (Rh), ruthenium (Ru) or a combination of the above materials.

The monolithic array chip 1′, 2′, 3′, 4′, 4B′, 5′, 6′, 7′, 8′, 9′, 10′ includes a plurality of light-emitting areas respectively corresponding to the light-emitting units 10, 20 and 30 to emit the visible lights such as the red light, the green light, and the blue light. In an embodiment, the monolithic array chip 1′, 2′, 3′, 4′, 4B′, 5′, 6′, 7′, 8′, 9′, 10′ includes a plurality of light-emitting areas respectively corresponding to the light-emitting units 10, 20 and 30 to emit the light of different wavelengths. For example, the monolithic array chip includes a first light-emitting area capable of emitting the red light located on the first light-emitting unit 10, a second light-emitting area capable of emitting the green light located on the second light-emitting unit 20, and a third light-emitting area capable of emitting the blue light located on the third light-emitting unit 30. In an embodiment, after the wafer including the light-emitting devices 1, 2, 3, 4, 4B, 5, 6, 7, 8, 9, 10 is transferred onto another carrier substrate (not shown) through the transfer process and the substrate 100 the undoped semiconductor layer 110 is removed, the monolithic array chip 1′, 2′, 3′, 4′, 4B′, 5′, 6′, 7′ or 8′ is disposed on the carrier substrate. Each of the light-emitting units 10, 20, and 30 is configured to emit the light having a peak wavelength λ, and the peak wavelength λ is at least 380 nm and/or not greater than 490 nm.

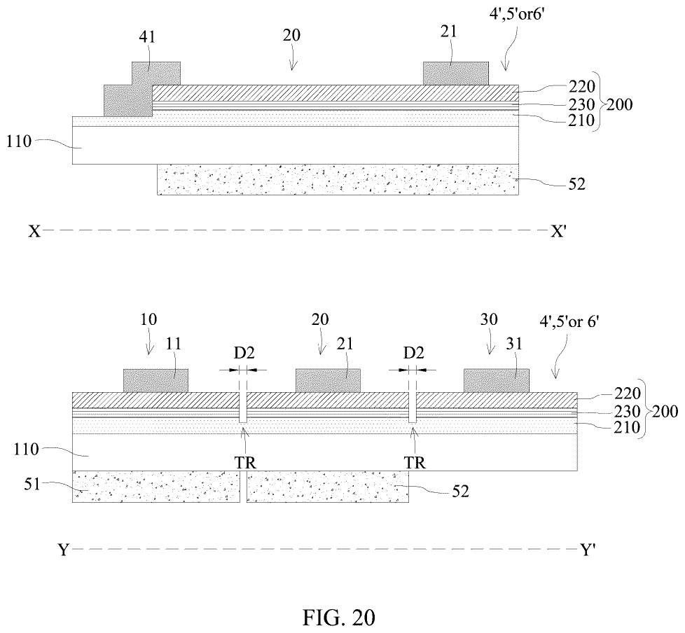

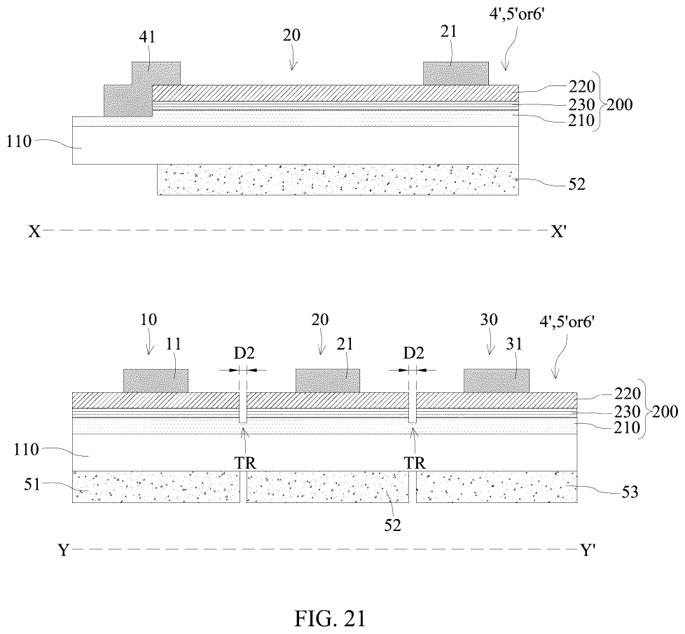

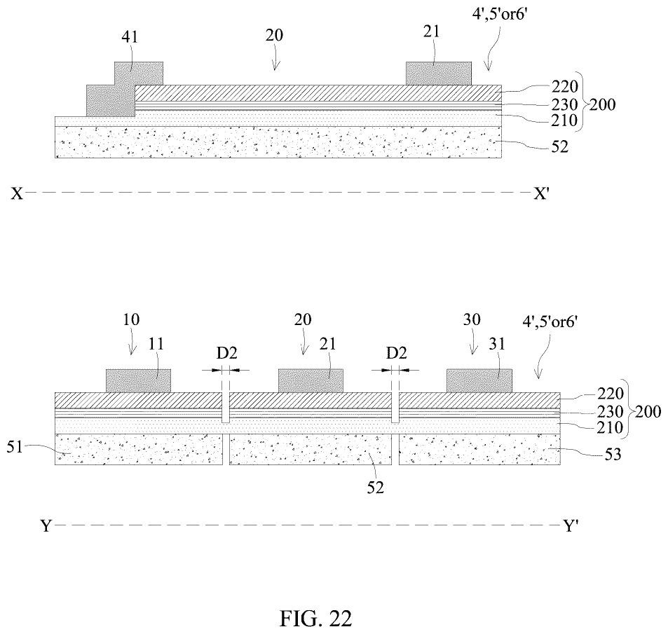

FIG. 20 illustrates the cross-sectional view that the wavelength conversion layers 51, 52 are located on the light-emitting units 10, 20 of the monolithic array chip 1′, 2′, 3′, 4′, 5′, 6′ or 7′ along the lines X-X′ and Y-Y′ in FIGS. 3-5A, FIG. 6A and FIGS. 7-9. FIGS. 21-22 illustrate the cross-sectional views that the wavelength conversion layers 51, 52, 53 are located on the light-emitting units 10, 20, 30 of the monolithic array chip 1′, 2′, 3′, 4′, 5′, 6′ or 7′ along the lines X-X′ and Y-Y′ in FIGS. 3-5A, FIG. 6A and FIGS. 7-9. FIG. 24 illustrates the cross-sectional view that the wavelength conversion layers 51, 52 are located on the light-emitting units 10, 20 of the monolithic array chip 8′, 9′, 10′ along the line Y-Y′ in FIGS. 10-12. FIG. 25 illustrates the cross-sectional view that the wavelength conversion layers 51, 52, 53 are located on the light-emitting units 10, 20, 30 of the monolithic array chip 8′, 9′, 10′ along the line Y-Y′ in FIGS. 10-12.

In an embodiment, as shown in FIGS. 20-22 and FIGS. 24-25, when the light-emitting units 10, 20, and 30 of the monolithic array chip 1′, 2′, 3′, 4′, 4B′, 5′, 6′, 7′, 8′, 9′, 10′ are configured to emit the blue light having a peak wavelength λ, a first wavelength conversion layer 51 is disposed on one of the plurality of light-emitting units 10, 20 and 30. The first wavelength conversion layer 51 absorbs the light having the peak wavelength λ to emit the first converted light (such as the green light) having a first converted wavelength λ1, wherein the first converted wavelength λ1 is longer than the peak wavelength λ. In an embodiment, the first converted wavelength λ1 is greater than 500 nm and/or not greater than 600 nm. A second wavelength conversion layer 52 is disposed on another one of the plurality of light-emitting units 10, 20 and 30. The second wavelength conversion layer 52 absorbs the light having the peak wavelength λ to emit the second converted light (such as the red light) having a second converted wavelength 22, wherein the second converted wavelength λ2 is longer than the first converted wavelength λ1. In an embodiment, the second converted wavelength λ2 is greater than 600 nm and/or not greater than 650 nm. In an embodiment, the monolithic array chip 1′, 2′, 3′, 4′, 5′, 6′, 7′, 8′, 9′, 10′ comprises a plurality of light-emitting areas to provide different wavelengths (the peak wavelength λ, the first converted wavelength λ1 and the second converted wavelength λ2).

In another embodiment, when the light-emitting units 10, 20, 30 of the monolithic array chip 1′, 2′, 3′, 4′, 4B′, 5′, 6′, 7′, 8′, 9′, 10′ are configured to emit the UVC light with a peak wavelength λ, as shown in FIGS. 21, 22 and 25, the first wavelength conversion layer 51 is disposed on the first light-emitting unit 10, the second wavelength conversion layer 52 is disposed on the second light-emitting unit 20, and the third wavelength conversion layer 53 is disposed on the third light-emitting unit 30. The first wavelength conversion layer 51 absorbs the light having the peak wavelength λ to emit the first converted light with the first converted wavelength λ1 that is longer than the peak wavelength λ. The second wavelength conversion layer 52 can absorb the light having the peak wavelength λ to emit the second converted light having the second converted wavelength λ2 that is longer than the first converted wavelength λ1, and the third wavelength conversion layer 53 can absorb the light having the peak wavelength λ to emit the third converted light having the third converted wavelength λ3 that is different from the first converted wavelength λ1 and the second converted wavelength λ2. Specifically, the first converted wavelength λ1 may be the green light, the second converted wavelength λ2 may be the red light, and the third converted wavelength λ3 may be the blue light.

In an embodiment, the first wavelength conversion layer 51, the second wavelength conversion layer 52, and the third wavelength conversion layer 53 include phosphors, organic molecules, or quantum dots. The first wavelength conversion layer 51, the second wavelength conversion layer 52 and/or the third conversion wavelength 53 are disposed on the light-emitting units 10, 20 and 30 to convert the light having the peak wavelength λ, so that the monolithic array chip 1′, 2′, 3′, 4′, 5′, 6′, 7′, 8′, 9′, 10′ can emit the light having different wavelengths. When the external power supply is electrically connected to the common electrode 41 and is selectively electrically connected to the first electrode 11, the second electrode 21, and/or the third electrode 3, the light-emitting units 10, 20 and 30 of the monolithic array chip can be selected to separately or simultaneously light up to emit the light with different wavelengths through the wavelength conversion layer.

The first, second, and third light-emitting units 10, 20, and 30 of the embodiment can be provided as the light-emitting unit G (green sub-pixel) capable of emitting the green light, the light-emitting unit R (red sub-pixel) capable of emitting the red light and the light-emitting unit B (blue sub-pixel) capable of emitting the blue light illustrated in FIG. 1. The common electrode 41 provided as the first electrical contact and the second electrical contact (the first electrode 11, the second electrode 21 and the third electrode 31) located on each light-emitting unit 10, 20, 30 can selectively control the luminescence of each light-emitting unit 10, 20, 30 of the monolithic array chip 1′, 2′, 3′, 4′, 5′, 6′, 7′, 8′, 9′ or 10′. For example, only light up the blue sub-pixel, only light up the green sub-pixel, or only light up the red sub-pixel. In addition, multiple sub-pixels can also be combined to emit the blue-green light, the blue-red light, the red-green light, or the red-green-blue light.

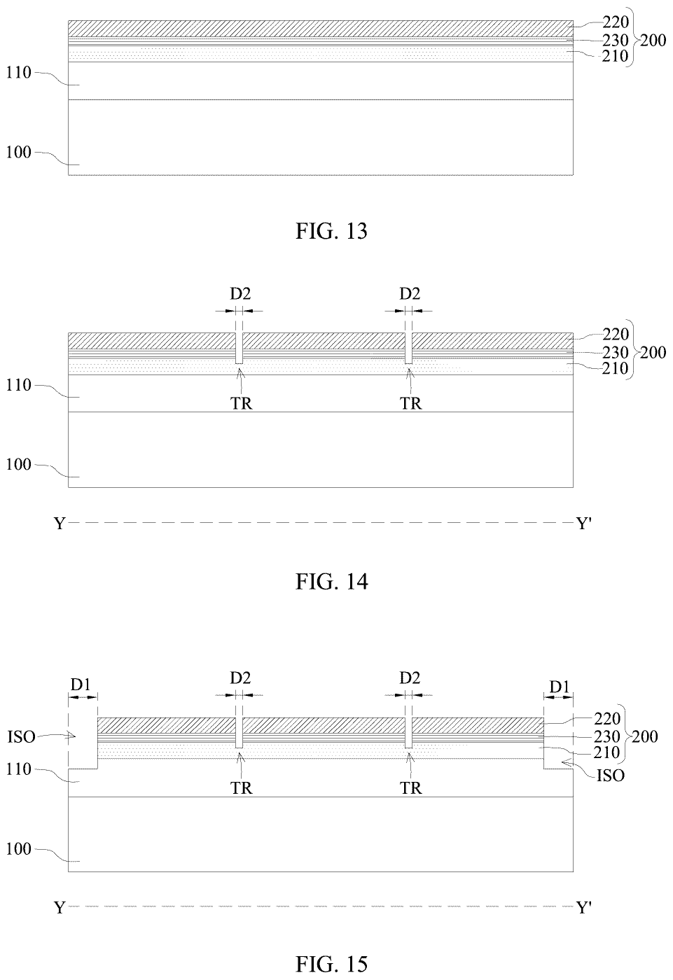

In an embodiment, as shown in FIG. 13, a manufacturing method of the monolithic array chip 1′, 2′, 3′, 4′, 5′, 6′, 7′, 8′, 9′, 10′ includes providing the substrate 100. The substrate 100 includes a growth substrate. The growth substrate is provided to epitaxially grow the epitaxy stack and includes but is not limited to a sapphire substrate, a silicon substrate, a silicon carbide substrate, a gallium arsenide (GaAs) substrate, a gallium nitride (GaN) substrate, or an aluminum nitride (AlN) substrate. The semiconductor stack 200 is formed on the growth substrate by, for example, a metal organic vapor deposition (MOCVD) method to sequentially form a buffer layer (not shown), the undoped semiconductor layer 110, the first semiconductor layer 210, the active layer 230 and the second semiconductor layer 220 on an upper surface of the substrate 100. The semiconductor stack 200 can emit the light having the peak wavelength λ. In another embodiment, the substrate 100 includes a bonding substrate. After epitaxially growing the epitaxial stack on a growth substrate (not shown), the epitaxial stack on the growth substrate is transferred to the bonding substrate through the wafer bonding process, and the bonding substrate and the epitaxial stack are bonded through a bonding layer (not shown). After removing the growth substrate from the epitaxial stack, the epitaxial stack with the bonding substrate continues to the manufacturing steps after FIG. 14. In an embodiment, the material of the bonding layer includes polymer materials such as benzocyclobutene (BCB), epoxy, polyimide or silicone, or dielectric materials such as aluminum oxide (Al₂O₃) or silicon oxide (SiO₂).

In an embodiment, FIG. 14 illustrates a cross-sectional view along the line Y-Y′ in FIGS. 3-5A and FIGS. 6A-12. As shown in FIG. 14, a first mask (not shown) can be used for selectively removing a part of the epitaxial stack to expose a partial upper surface of the epitaxial stack and form the trench TR. For example, the upper surface of the first semiconductor layer 210 is exposed.

In an embodiment, FIG. 15 and FIG. 16 illustrate the cross-sectional views along the line Y-Y′ in FIGS. 3-5A and FIGS. 6A-12 before forming the electrode. As shown in FIG. 15, a second mask (not shown) can be used for selectively removing a part of the epitaxial stack to expose a partial upper surface of the epitaxial stack and form the separation lane ISO. For example, the upper surface of the undoped semiconductor layer 110 is exposed. In other embodiments, as shown in FIG. 16, a portion of the epitaxial stack can be selectively removed to expose a portion of the upper surface of the substrate 100 to form the separation lane ISO. The first mask and the second mask can be a patterned photoresist layer or other photoresist materials, such as silicon dioxide. Taking the patterned photoresist layer as an example, it can be formed through the conventional technology, such as photolithography or electron-beam lithography. For example, a photoresist layer is coated on the epitaxial stack, the photoresist is exposed through an appropriate light source, and a first pattern is transferred onto the photoresist layer, thereby defining the pattern of the plurality of light-emitting units 10, 20, and 30. The photoresist is dry-etched through the reactive ion etching to form the plurality of light-emitting units.

FIG. 17 illustrates a cross-sectional view along the line Y-Y′ in FIGS. 3-5A and FIGS. 6-9 after forming the electrodes. FIG. 18A illustrates a cross-sectional view along the line X-X′ in FIGS. 6A and 7-8 after forming the electrodes. FIG. 18B illustrates a cross-sectional view along the line X-X′ in FIGS. 3-5A and 9 after forming the electrodes. As shown in FIG. 17, the second electrical contacts (the first electrode 11, the second electrode 21, and the third electrode 31) are respectively formed on the light-emitting units 10, 20, 30. As shown in FIGS. 18A and 18B, the first electrical contact (the common electrode 41) is formed on the common first semiconductor layer 210. In the embodiment, the common electrode 41, the first electrode 11, the second electrode 21 and the third electrode 31 are located on the same side of the semiconductor stack 200 to form the flip-chip electrode structure. In some embodiments, before forming the second electrical contact (the first electrode 11, the second electrode 21 and the third electrode 31) and the first electrical contact (the common electrode 41), an insulating layer can be formed on the semiconductor stack 200. The insulating layer includes a single layer structure or a multi-layer structure. The multi-layer structure includes the material layers composed of two or more different insulating materials that are stacked one or more times to form a reflective structure, such as the Distributed Bragg Reflector (DBR) to reflect the light emitted from the semiconductor stack 200. A part of the insulating layer on the semiconductor stack 200 can be removed by etching to form a plurality of openings, and then the second electrical contacts (the first electrode 11, the second electrode 21 and the third electrode 31) and the first electrical contact (the common electrode 41) are formed at positions corresponding to the plurality of openings.

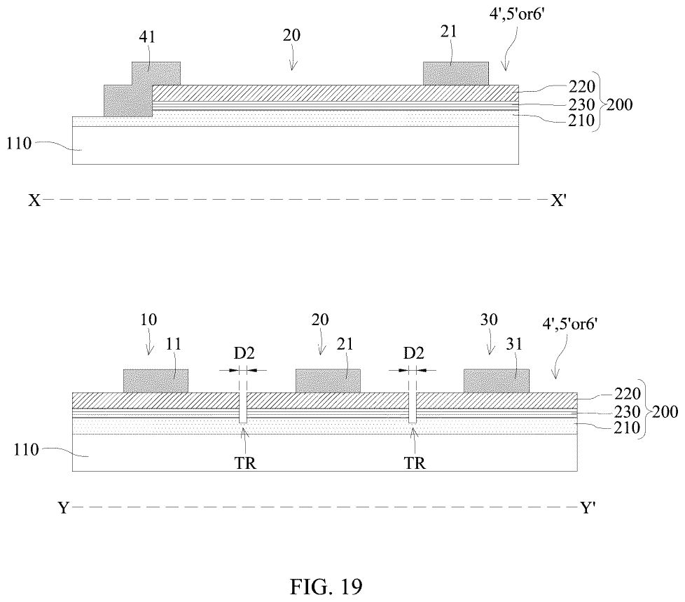

In an embodiment, as shown in FIGS. 19-22, the monolithic array chips 1′, 2′, 3′, 4′, 5′, 6′, 7′ having the flip-chip electrode structures can be separated from the substrate 100 through a transfer process. In an embodiment, the transfer process includes disposing the monolithic array chip 1′, 2′, 3′, 4′, 5′, 6′, 7′ on a carrier substrate (not shown) for removing the growth substrate 100 (as shown in FIGS. 19-21), or removing the substrate 100 and the undoped semiconductor layer 110 (as shown in FIG. 22). In another embodiment, the transfer process is provided by weakening the bonding between the monolithic array chip 1′, 2′, 3′, 4′, 5′, 6′, 7′ and the substrate 100, so that the monolithic array chip can be separated from the substrate 100 and disposed on the carrier substrate to form the monolithic array chips 1′, 2′, 3′, 4′, 5′, 6′, 7′ without the substrate 100. For example, the individual monolithic array chip 1′, 2′, 3′, 4′, 5′, 6′, 7′ is irradiated with laser so that the individual monolithic array chip 1′, 2′, 3′, 4′, 5′, 6′, 7′ is separated from the substrate 100 without contacting the carrier substrate and disposed on the carrier substrate.

FIG. 23 illustrates a cross-sectional view along the line Y-Y′ in FIGS. 10-12 after forming the electrodes. In another embodiment, the monolithic array chips 8′, 9′, 10′ having the vertical electrode structures can be separated from the substrate 100 through the transfer process. The light-emitting device 8, 9, 10 can be disposed on the carrier substrate (not shown) for removing the substrate 100 and the undoped semiconductor layer 110, or weakening the bonding between the monolithic array chip 8′, 9′, 10′ and the substrate 100 to cause the monolithic array chips 8′, 9′, 10′ being separated from the substrate 100 and disposed on the carrier substrate, thus forming the monolithic array chip 8′, 9′, 10′ without the substrate 100. As shown in FIG. 23, after removing the substrate 100 and the undoped semiconductor layer 110, the first electrical contact (common electrode 41) is formed on the common first semiconductor layer 210. The common electrode 41 and the first electrode 11, the second electrode 21 and the third electrode 31 are located on opposite sides of the semiconductor stack 200 to form the vertical electrode structure. In the embodiment, the undoped semiconductor layer 110 can be removed by etching or grinding, and the growth substrate 100 can be removed by a physical or chemical lift-off method, such as laser lift-off (LLO).

The first electrical contact formed on the common first semiconductor layer serves as the common electrode 41. The first electrical contact and the second electrical contact (the first electrode 11, the second electrode 21 and the third electrode 31) located on the light-emitting unit 10, 20, 30 can selectively control each of the light-emitting units 10, 20, 30 of the monolithic array chip 1′, 2 ‘, 3’, 4′, 5′, 6′, 7′ or 8′ to light up. In an embodiment, the second electrical contact includes the first electrode 11 on the first light-emitting unit 10, the second electrode 21 on the second light-emitting unit 20, and the third electrode 31 on the third light-emitting unit 30.

As shown in FIG. 3, the first electrical contact (the common electrode 41) and the second electrical contact (the first electrode 11, the second electrode 21 and the third electrode 31) each includes a width W1 less than 20 μm or 10 μm, and/or includes an area not larger than the following area: 10 μm×10 μm or 5 μm×5 μm. In an embodiment, the area size of the first electrical contact (the common electrode 41) and the area size of each of the second electrical contacts (the first electrode 11, the second electrode 21 and the third electrode 31) are the same. The first electrical contact (the common electrode 41) and each of the second electrical contacts (the first electrode 11, the second electrode 21, and the third electrode 31) includes the same shape, length, and width. In an embodiment, the length is approximately the same as the width. In an embodiment, there is a distance W2 between the first electrical contact (the common electrode 41) and the second electrical contact (the first electrode 11, the second electrode 21 or the third electrode 31), or between the adjacent electrodes, wherein the minimum width of the distance W2 is greater than or equal to the length or width of the above-mentioned electrode, and is less than or equal to ½ or ⅓ of the length L2, L2′ of the side of the monolithic array chip, such as greater than or equal to 3 μm or 10 μm and less than or equal to 25 μm or 15 μm, or the minimum width of the distance W2 between the two closest second electrical contacts (for example, the first electrode 11 and the second electrode 21, or the second electrode 21 and the third electrode 31) is greater than or equal to the length or width of the above-mentioned electrode, for example greater than or equal to 3 μm or 10 μm, and less than or equal to 25 μm or 15 μm. FIGS. 4-12 illustrate that the dimensions with the same symbols are similar to those disclosed in FIG. 1 and that will not be described again here.

In an embodiment, the electrode design on each of the light-emitting units of the monolithic array chip includes a rectangular shape of the same size, and the placement of the adjacent electrodes must meet the minimum width of the distance W2 being at least one electrode length or width. After the layout of each electrode is set, the shape of each light-emitting unit can be designed as required. The distance between adjacent light-emitting units must meet the design of the minimum width D2 of the trench TR and/or the distance S described above.

In an embodiment, the highest portion of the top surface of the first electrical contact (the common electrode 41) and the highest portion of the top surface of the second electrical contact (each of the first electrode 11, the second electrode 21 and the third electrode 31) are provided on the same horizontal surface to improve the yield rate when the first electrical contact and each second electrical contact are subsequently bonded to the carrier substrate or display backplane. The first electrical contact (the common electrode 41) includes an electrode area in the cross-sectional view larger than that of the second electrical contact (each of the first electrode 11, the second electrode 21 and the third electrode 31).

Under the current injection, the contact resistance between the electrical contact and the epitaxial layer affects the diffusion length of the carriers. Therefore, the shape and/or the size of each of the light-emitting units 10, 20, 30 and the size of the second electrical contact (the first electrode 11, the second electrode 21 and the third electrode 31) corresponding thereto must be limited.

FIGS. 3-12 illustrate the top views of the monolithic array chip 1′, 2′, 3′, 4′, 4B′, 5′, 6′, 7, 8′, 9′, 10′ in accordance with an embodiment of the present application. Three light-emitting units 10, 20, and 30 are formed on the first semiconductor layer 210. The first light-emitting unit 10 is configured to emit a light having a peak wavelength A corresponding to the blue light. The second light-emitting unit 20 is configured to emit a light having a peak wavelength A corresponding to the blue light. The third light-emitting unit 30 is configured to emit a light having a peak wavelength λ corresponding to the blue light. Under the current injection, the carriers are injected through the p-type and n-type regions to provide the emission after recombination, and it is understood by the person having the ordinary skill in the art that the electrical connection provided to inject the carriers through the p-type and n-type regions of the LED can be achieved in different ways. For example, the monolithic array chips 1′, 2′, 3′, 4′, 4B′, 5′, 6′, 7′ or 8′ can be coupled to a complementary metal oxide semiconductor (CMOS) backplane to control the light emitting of the light-emitting units 10, 20, and 30. Although only three light-emitting units 10, 20, and 30 are shown in the top view, any appropriate number of light-emitting units can be used to form the monolithic array chips 1′, 2′, 3′, 4′, 4B′, 5′, 6′, 7′ or 8′ in other embodiments.

The light-emitting units 10, 20, 30 are arranged as a part of the monolithic array chip 1′, 2′, 3′, 4′, 4B′, 5′, 6′, 7, 8′, 9′, 10′. The trench TR provided between the light-emitting units 10, 20, 30 is provided to reduce the optical interference between the light-emitting units 10, 20, 30. By reducing the optical interference between the light-emitting units 10, 20, 30, the distinction between the colors of the light emitted from the light-emitting units 10, 20, 30 is improved. The trench TR can be a reflective area including a metal material or a Bragg Reflector, for example. In the reflective area, the light absorption on the specific directions is reduced and the reflected light emitted towards the specific directions is reused, i.e., the directions that is not related to the emission direction of the emissive surface associated with the pixel. In other embodiments, the alternative and/or the additional materials are used to form the reflective area. Although the trench TR exposes the first semiconductor layer 210 as illustrated in FIGS. 1-8, any appropriate configuration of the trench TR can be used.

The present application discloses the method of manufacturing the monolithic array chips 1′, 2′, 3′, 4′, 4B′, 5′, 6′, 7′, 8′, 9′, 10′, on a single growth substrate 100 including transferring a plurality of monolithic array chips 1′, 2′, 3′, 4′, 4B′, 5′, 6′, 7′, 8′, 9′, 10′ to the temporary carrier substrate or the driving backplane having the circuit design, and separating the plurality of single array chips 1′, 2′, 3′, 4′, 4B′, 5′, 6′, 7′, 8′, 9′, 10′ from the growth substrate 100, which provides higher integration density, smaller light-emitting units 10, 20, 30, and smaller spacing (i.e., the higher array resolution) to form a full-color display. The periphery of the light-emitting area of the individual light-emitting units 10, 20, 30 in the monolithic array chip 1′, 2′, 3′, 4′, 4B′, 5′, 6′, 7′ or 8′ is formed by the etching process. A portion of the light-emitting area is removed during the etching process, thereby electrically isolating the individual light-emitting units 10, 20, 30 to allow the electrical power independently injected into each of the light-emitting units 10, 20, 30.

In an embodiment of the present application, the plurality of light-emitting devices 1, 2, 3, 4, 4B, 5, 6, 7, 8, 9, 10 is formed on the wafer (not shown) served as the substrate 100, the plurality of light-emitting devices 1, 2, 3, 4, 4B, 5, 6, 7, 8, 9, 10 is separated from the substrate 100 through the aforementioned transfer process to form the monolithic array chips 1′, 2′, 3′, 4′, 4B′, 5′, 6′, 7′, 8′, 9′ or 10′ without having the substrate 100. FIG. 26 illustrates a partial top view of a light-emitting module 10000 in accordance with an embodiment. The light-emitting module 10000 includes a circuit board (not shown), and a plurality of monolithic array chips 1′, 2′, 3′, 4′, 4B′, 5′, 6′, 7′, 8′, 9′ or 10′ located on the circuit board, wherein the plurality of monolithic array chips 1′, 2′, 3′, 4′, 4B′, 5′, 6′, 7′, 8′, 9′ or 10′ is separated from each other by a separation lane G1, G2. The separation lane G1, G2 each includes a width less than 1000 μm, 750 μm, 500 μm, 300 μm or 150 μm, but larger than 10 μm or 50 μm.

To simplify the explanation, the light-emitting device 3 shown in FIG. 5A is illustrated as an example below. The elements with the same symbols in FIGS. 3-12 as those in FIG. 5A can be understood as having the same functions, and the same content will not be described again. In an embodiment, the wafer (not shown) can be provided as the substrate 100 of the light-emitting device 1, 2, 3, 4, 4B, 5, 6, 7, 8, 9 or 10 illustrated in FIGS. 3-12. As shown in FIG. 5A, the separation lane ISO surrounds the first semiconductor layer 210, wherein the separation lane ISO comprises a width D1′ in a direction parallel to the X-direction and a width D1 in a direction parallel to the Y-direction. A spacing g, g′ is formed between any two adjacent of the monolithic array chips 1′, 2′, 3′, 4′, 4B′, 5′, 6′, 7′, 8′, 9′ or 10′ on the wafer. The width of the spacing g, g′ is respectively two times of the width D1, D1′ of the separation lane ISO of the light-emitting device 1, 2, 3, 4, 4B, 5, 6, 7, 8, 9, 10. As shown in FIG. 5B, the width of the spacing g, g′ between any two adjacent monolithic array chips 3′ on the wafer is respectively two times of the width D1, D1′ of the separation lane ISO of the light-emitting device 1, 2, 3, 4, 4B, 5, 6, 7, 8, 9, 10, in other words, g=2×D1, g′=2×D1′. As shown in FIG. 5C, the monolithic array chip 1′, 2′, 3′, 4′, 4B′, 5′, 6′, 7′, 8′, 9′ or 10′ can be separated from the substrate 100 through the transfer process. In an embodiment, as shown in FIGS. 5B-5C and 26, according to the needs of the user or application, when the monolithic array chip 1′, 2′, 3′, 4′, 4B′, 5′, 6′, 7, 8′, 9′, 10′ on the chip on wafer (COW) stage illustrated in FIG. 5B is separated from the substrate 100 through laser lift-off or chemical lift-off as shown in FIG. 5C, and the monolithic array chip 1′, 2′, 3′, 4′, 4B′, 5′, 6′, 7′, 8′, 9′, 10′ is disposed onto the carrier substrate or the driving backplane on the chip on carrier (COC) stage or the chip on backplane (COB) stage illustrated in FIG. 26, in a direction parallel to the X-direction, the width of the separation lane G1 satisfies the formula G1=n×L1+2×D1, wherein n can be zero or a positive integer. In a direction parallel to Y-direction, the width of the separation lane G2 satisfies the formula G2=n×L1′+2×D1′, where n may be zero or a positive integer. In an embodiment, the separation lane G1 and the separation lane G2 may comprise the same or different width. For example, when the width D1, D1′ of the separation lane ISO is between 1.5 μm-3 μm, 2.5 μm-10 μm or 2 μm-5 μm, the width of the separation lane G1, G2 is between 3 μm-6 μm, 5 μm-20 μm or 4 μm-10 μm.

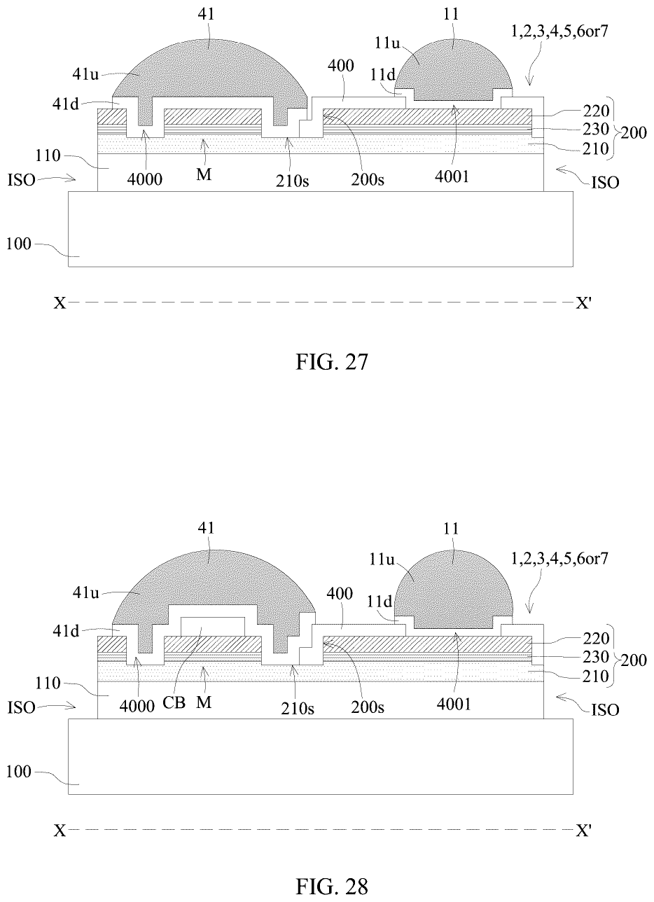

FIGS. 27-30 illustrate the cross-sectional views along the line X-X′ of FIGS. 3-9. The dimensions and the materials with the same symbols disclosed in FIGS. 27-30 are similar to those disclosed in FIGS. 3-9, and that will not be described again here.

As shown in FIGS. 3-9, since the light-emitting device 1, 2, 3, 4, 5, 6, 7 includes multiple electrodes (the first, second and third electrodes 11, 21, 31 and the common electrode 41), the multiple electrodes can be connected to the package substrate by the eutectic bonding or the solder bonding. In an embodiment, the top surface shape of the plurality of electrodes may be a dome shape. In another embodiment, the top surface of the plurality of electrodes comprises a flat surface. When the top surfaces of the multiple electrodes are not at the same height from the surface of the substrate, the monolithic array chips 1′, 2′, 3′, 4′, 5′, 6′, 7′ is prone to skewing when they are flip-chip bonded to the carrier substrate or the driving backplane having the circuit design, thus affecting the light-emitting effect of the light emitting components 1, 2, 3, 4, 5, 6, 7. To the backlight and the micro LED related products that require the high light emitting effects, the above situations are easy to happen.

As shown in FIGS. 27-30, after removing a part of the semiconductor stack 200 by etching to expose the first surface 210s of the first semiconductor layer 210, there is a gap between 1 μm-2 μm (for example, 1.4 μm) formed between the second semiconductor layer 220 and the exposed first surface 210s. When the common electrode 41 is formed on the exposed first semiconductor layer 210, a height difference is formed between the common electrode 41 and the first, second, and third electrodes 11, 21, and 31. The application provides a light-emitting device 1, 2, 3, 4, 5, 6, 7, including the first semiconductor layer 210, the common electrode 41 located on the first semiconductor layer 210, the first light-emitting unit 10 having the first electrode 11 located on the first semiconductor layer 210, the second light-emitting unit 20 with the second electrode 21 located on the first semiconductor layer 210, and the third light-emitting unit 30 with the third electrode 31 located on the first semiconductor layer 210, wherein the light-emitting unit 10, the second light-emitting unit 20, and the third light-emitting unit 30 are separated from each other by the trench TR. The trench TR includes a minimum width D2 less than or equal to 3 μm, and the common electrode 41 and any one or all of the first electrode 11, the second electrode 21, and the third electrode 31 are of the same height.

In accordance with an embodiment of the present application, the step height difference between the second semiconductor layer 220 and the first surface 210s is compensated through the size design of the common electrode 41 and the structure design under the common electrode 41.

In the embodiment, the common electrode 41 includes a top-view area larger than the top-view area of any one of the first electrode 11, the second electrode 21 and the third electrode 31. For example, the top view area of the common electrode 41 may be 5.5×5.5 μm², and the top view area of any one of the first electrode 11, the second electrode 21 and the third electrode 31 may be 4×4 μm².

In the embodiment, the light-emitting device 1, 2, 3, 4, 5, 6, 7 further includes an insulating reflective structure 400 covering the first surface 210s of the first semiconductor layer 210, the semiconductor stack 200 and the sidewall 200s thereof to improve the light extraction efficiency of the light-emitting device 1, 2, 3, 4, 5, 6, 7. The insulating reflective structure 400 can be a single layer or comprises multiple layers alternately stacked to form the Distributed Bragg Reflector (DBR). In an embodiment, the insulating reflective structure 400 includes a thickness between 0.5 μm and 2.5 μm, such as 1 μm or 1.5 μm.

As shown in FIGS. 27-30, the insulating reflective structure 400 includes a common insulating reflective structure opening 4000 located under the common electrode 41, a first insulating reflective structure opening 4001 located under the first electrode 11, a second insulating reflective structure opening (not shown) located under the second electrode 21 shown in FIGS. 3-12, and a third insulating reflective structure opening (not shown) located under the third electrode 31 shown in FIGS. 3-12. The common electrode 41, the first electrode 11, the second electrode 21 and/or the third electrode 31 includes a lower electrode (e.g., the lower electrode 11d, 41d) composed of one material selected from one of the following: aluminum (Al), gold (Au), tungsten (W), platinum (Pt), iridium (Ir), silver (Ag), copper (Cu), nickel (Ni), titanium (Ti), chromium (Cr) and the alloy of the above materials. The common electrode 41, the first electrode 11, the second electrode 21 and/or the third electrode 31 further includes an upper electrode (e.g., the upper electrode 11u, 41u) including the conductive material, such as Sn, Au or AuSn alloy.

In an embodiment of the present application, as shown in FIG. 27, the light-emitting device 1, 2, 3, 4, 5, 6, 7 further includes a semiconductor mesa M located between the common electrode 41 and the substrate 100. The semiconductor mesa M includes a top-view area (e.g., 8-10 μm²) smaller than the top-view area of the first light-emitting unit 10, the second light-emitting unit 20, or the third light-emitting unit 30. The semiconductor mesa M located under the common electrode 41 and the semiconductor stack 200 located under the first electrode 11 comprise the same material and structure. In the embodiment, the semiconductor mesa M comprises a thickness between 1 μm-2 μm to compensate the step height difference between the second semiconductor layer 220 and the first surface 210s so that the common electrode 41 and any one or all of the first electrode 11, the second electrode 21 or the third electrode 31 are of the same height. In the embodiment, the common electrode 41 contacts the first surface 210s around the semiconductor mesa M through the common insulating reflective structure opening 4000 to form an electrical connection with the first semiconductor layer 210, so that the semiconductor mesa M includes a projected area smaller than that of the common electrode 41. In the embodiment, the semiconductor mesa M includes a width between 2.5 μm-3.5 μm. The common insulation reflective structure opening 4000 includes an annular opening with a width ranging from 0.5-1 μm to surround the semiconductor mesa M. The contact area between the common electrode 41 and the first surface 210s is the area of the outermost contour of the common insulating reflective structure opening 4000 projected on the substrate 100 minus the area of the semiconductor mesa M projected on the substrate 100. In an embodiment, the contact area between the common electrode 41 and the first surface 210s is 10-12 μm².

In an embodiment of the present application, as shown in FIG. 28, the light-emitting device 1, 2, 3, 4, 5, 6, 7 includes a current blocking structure CB located under the common electrode 41 or between the electrode 41 and the semiconductor mesa M. The material of the current blocking structure CB includes insulating materials, such as silicon oxide, silicon nitride, or aluminum oxide. The current blocking structure CB comprises a single layer or multiple layers alternately stacked, such as a Distributed Bragg Reflector (DBR). In the embodiment, the current blocking structure CB comprises a thickness between 1 μm-2 μm to compensate the step height difference between the second semiconductor layer 220 and the first surface 210s so that the common electrode 41 and any one or all of the first electrode 11, the second electrode 21 and the third electrode 31 are of the same height. In another embodiment, the common electrode 41 contacts the current blocking structure CB and the first surface 210s around the semiconductor mesa M to form an electrical connection with the first semiconductor layer 210, so that the current blocking structure CB includes a projected area smaller than that of the common electrode 41. In an embodiment of the present application, the projected area of the current blocking structure CB is 50%˜80% of the projected area of the common electrode 41.

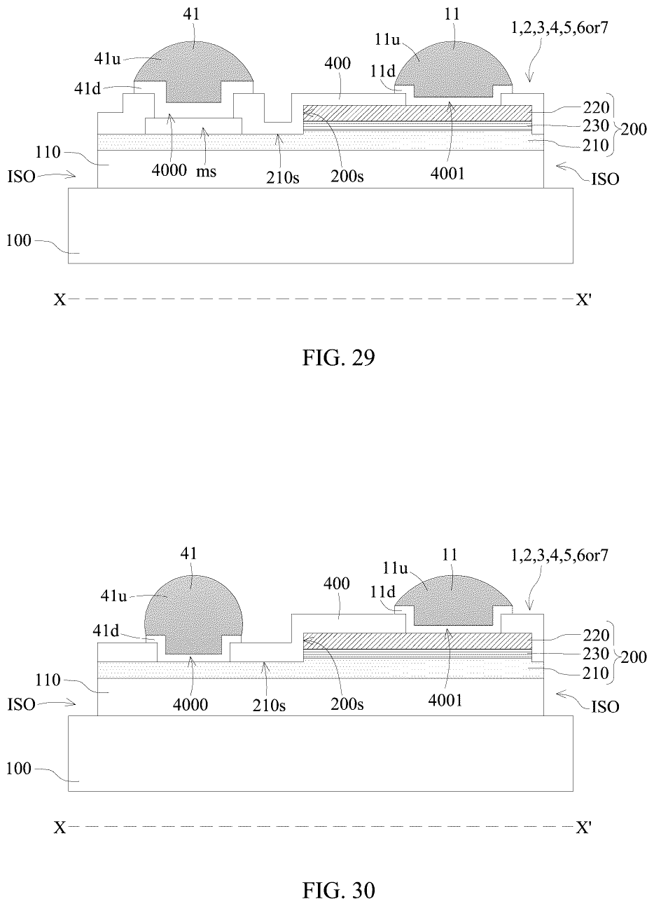

In an embodiment of the present application, as shown in FIG. 29, the light-emitting device 1, 2, 3, 4, 5, 6, 7 further includes a pad metal structure ms located under the common electrode 41. The pad metal structure ms comprises one material selected from one of the following: aluminum (Al), gold (Au), tungsten (W), platinum (Pt), iridium (Ir), silver (Ag), copper (Cu), nickel (Ni), titanium (Ti), chromium (Cr) and the alloy of the above materials. The pad metal structure ms includes a thickness between 1 μm-2 μm to compensate the step height difference between the second semiconductor layer 220 and the first surface 210s so that the common electrode 41 and any one or all of the first electrode 11, the second electrode 21 and the third electrode 31 are of the same height. The common electrode 41 contacts the pad metal structure ms through the common insulating reflective structure opening 4000 to form an electrical connection with the first semiconductor layer 210. In the embodiment, the common insulation reflective structure opening 4000 comprises a circular hole or a rectangular hole with a diameter or a width of 2-4 μm. In the embodiment, the pad metal structure ms includes a projected area that is larger, smaller, or the same as the projected area of the common electrode 41. In an embodiment, the pad metal structure ms can be located above or under the insulating reflective structure 400, disposed corresponding to the common insulating reflective structure opening 4000, and contacts with the first semiconductor layer 210 through the common insulating reflective structure opening 4000. The common electrode 41 is formed on the pad metal structure ms and forms an electrical connection with the first semiconductor layer 210 through the common insulating reflective structure opening 4000.

In an embodiment of the present application, as shown in FIG. 30, the common electrode 41 includes a thickness greater than that of the first electrode 11, the second electrode 21, or the third electrode 31. The thickness difference between the thickness of the common electrode 41 and the thickness of the first electrode 11, the second electrode 21 or the third electrode 31 may be between 1 μm-2 μm to compensate the step height difference between the surface of the second semiconductor layer 220 and the first semiconductor layer 210, which makes the common electrode 41 have the same height as any one or all of the first electrode 11, the second electrode 21 and the third electrode 31. In the embodiment, the common electrode 41 and the first electrode 11, the second electrode 21 or the third electrode 31 are formed by different coating processes. During the manufacturing process of the common electrode 41, the area of the common electrode 41 can be increased by increasing the area of the metal film layer thereof to be larger than that of other electrodes, or the thickness of the metal film layer of the common electrode 41 can be thickened or the number of stacked film layers of the common electrode 41 can be increased to compensate the step height difference between the second semiconductor layer 220 and the exposed surface of the first semiconductor layer 210.

In some embodiments, the substrate 100 includes a gallium arsenide (GaAs) wafer for the epitaxial growth of aluminum gallium indium phosphide (AlGaInP), or a sapphire (Al₂O₃) wafer, a gallium nitride (GaN) wafer, a silicon carbide (SiC) wafer, or an aluminum nitride (AlN) wafer for the epitaxial growth of gallium nitride (GaN), indium gallium nitride (InGaN), or aluminum gallium nitride (AlGaN), but the present application is not limited to this, other suitable substrate materials are also applicable in the disclosure.

In some embodiments, the metal organic chemical vapor deposition (MOCVD), molecular beam epitaxy (MBE), hydride vapor phase (HVPE), physical vapor deposition (PVD), or the ion plating method is provided to form the buffer layer (not shown), the undoped semiconductor layer 110, the first semiconductor layer 210, the active layer 230, and the second semiconductor layer 220, wherein the physical vapor deposition method includes sputtering or evaporation.

The buffer layer (not shown) is provided to alleviate the lattice constant difference between the substrate 100 and the undoped semiconductor layer 110, reduce the epitaxial defect, and improve the epitaxial quality of the semiconductor layer grown thereon. In some embodiments, the buffer layer (not shown) includes an insulating material of Group V elements or Group VI elements, such as TiOₓ, AlₓN_{y}, AlₓO_{y}, AlₓO_{y}N_{z}, SiOₓ, or SiNₓ. In some embodiments, the buffer layer (not shown) includes a III-V group material, such as aluminum nitride (AlN), gallium nitride (GaN), or aluminum gallium nitride (AlGaN).

The undoped semiconductor layer 110 can prevent the crystal defect from propagating into the active layer 230. The undoped semiconductor layer 110 may include the n-type doping or not include the n-type doping. When the undoped semiconductor layer 110 does not include the n-type doping, the excellent crystallinity of the undoped semiconductor layer 110 can be maintained. Therefore, the undoped semiconductor layer 110 can be selected to not including the n-type doping, and the thickness of the undoped semiconductor layer 110 can be increased to reduce the defects of the undoped semiconductor layer 110. In some embodiments, the undoped semiconductor layer 110 includes the unintentional doping, such as carbon (C), oxygen (O), silicon (Si), hydrogen (H), or any combination of the above, and the unintentionally doping is not greater than 1E+18 atoms/cm³ or not greater than 1E+17 atoms/cm³.

In some embodiments, the undoped semiconductor layer 110 includes the undoped III-V semiconductor, for example, the undoped binary, ternary, or quaternary III-V semiconductor. In some embodiments, the undoped binary III-V semiconductor includes the undoped gallium nitride (GaN), but the present application is not limited thereto, other suitable undoped binary III-V semiconductors are also applicable to the disclosure. In some embodiments, the undoped ternary III-V semiconductor includes the undoped indium gallium nitride (InGaN) or aluminum gallium nitride (AlGaN), but the application is not limited thereto, other suitable undoped ternary III-V semiconductors are also applicable to the disclosure. In some embodiments, the undoped quaternary III-V semiconductor includes the undoped indium aluminum gallium nitride (InAlGaN), but the present application is not limited thereto, other suitable undoped quaternary III-V semiconductors are also applicable to the disclosure. In some embodiments, the maximum thickness of the undoped semiconductor layer 110 is less than 2 μm, for example, between 1.4 μm-1.8 μm or between 1.6 μm-1.7 μm.

In some embodiments, the first semiconductor layer 210 includes the n-type doped III-V semiconductor, for example, the n-type doped binary, ternary, or quaternary III-V semiconductor. In some embodiments, the n-type doped binary III-V semiconductor includes the n-type doped gallium nitride (GaN), but the present application is not limited thereto, other suitable n-type doped binary III-V semiconductors are also applicable to the disclosure. In some embodiments, the n-type doped ternary III-V semiconductor includes the n-type doped indium gallium nitride (InGaN) or aluminum gallium nitride (AlGaN), but the present application is not limited thereto, other suitable n-type doped ternary III-V semiconductors are also applicable to the disclosure. In some embodiments, the n-type doped quaternary III-V semiconductor includes the n-type doped indium aluminum gallium nitride (InAlGaN), but the present application is not limited thereto, other suitable n-type doped quaternary III-V semiconductors are also applicable to the disclosure. The n-type doping includes silicon (Si), carbon (C), germanium (Ge), or oxygen (O), but the present application is not limited thereto, and other suitable Group IV or Group VI elements are also applicable to the present application. In the embodiment, silicon (Si) is illustrated as an example. The n-type doping concentration of the first semiconductor layer 210 is less than or equal to 5E+19 atoms/cm³, or less than or equal to 2.5E+19 atoms/cm³, and greater than or equal to 2.5E+18 atoms/cm³, or greater than or equal to 1E+19 atoms/cm³. Since the greater the thickness of the first semiconductor layer 210 is, the lower of the resistance thereof is, thus the thickness of the first semiconductor layer 210 is preferably increased. However, as the thickness of the first semiconductor layer increases, the production cost is also increased. Therefore, in view of the manufacturing, the thickness of the first semiconductor layer 210 is less than 2 μm, for example, between 1.3 μm-1.7 μm, or between 1.5 μm-1.6 μm. In some embodiments, a ratio between the thickness of the first semiconductor layer 210 and the thickness of the undoped semiconductor layer 110 is greater than 0.8, for example, between 0.9-1.1.

In some embodiments, the active layer 230 includes a multiple quantum well (MQW) structure, for example, composed by alternately stacking one or more barrier layers having the energy barrier higher than that of the well layer, such as the gallium nitride (GaN) or the aluminum gallium nitride (AlGaN) material layer, and one or more well layers, such as the indium gallium nitride (InGaN) material layer, but the disclosure is not limited thereto, the multiple quantum well structure composed by alternately stacking the barrier layers and the well layers including other suitable III-V semiconductor materials is also applicable to the disclosure.

In some embodiments, the second semiconductor layer 220 includes the p-type doped III-V semiconductor, for example, the p-type doped binary, ternary, or quaternary III-V semiconductor. In some embodiments, the p-type doping includes magnesium (Mg), beryllium (Be), calcium (Ca), or strontium (Sr), but the present application is not limited thereto, and other suitable Group II elements are also applicable to the disclosure. In some embodiments, the p-type doped binary III-V semiconductor includes the p-type doped gallium nitride (GaN), but the application is not limited thereto, other suitable p-type doped binary III-V semiconductors are also applicable to the disclosure. In some embodiments, the p-type doped ternary III-V semiconductor includes the p-type doped indium gallium nitride (InGaN), the aluminum indium nitride (AlInN), or the aluminum gallium nitride (AlGaN), However, the present application is not limited thereto, and other suitable p-type doped ternary III-V group semiconductors are also applicable to the present disclosure. In some embodiments, the p-type doped quaternary III-V semiconductor includes the p-type doped indium aluminum gallium nitride (InAlGaN), but the present application is not limited thereto, other suitable p-type doped quaternary III-V semiconductors are also applicable to the disclosure.

In the traditional multi-color (RGB) LED display, the red, the blue, and the green LEDs are made of different semiconductor materials. For example, the sub-pixel capable of emitting the red light are made of InAlGaP material, and the sub-pixel capable of emitting the green light and the sub-pixel capable of emitting the blue light are made of InGaN materials with different indium contents. These sub-pixels manufactured from different LED wafers are transferred to a common carrier through the transfer process and combined into a pixel of a multi-color display apparatus. The current transfer process has to overcome the complex chip on carrier (COC) process and the high-cost laser transfer. When the resolution requirement of the display increases, these technical bottlenecks become more and more difficult as the size of the sub-pixel becomes smaller. In addition, since the red, the blue, and the green LEDs are made of different semiconductor materials, the optoelectronic characteristic of the red LED is difficult to match with those of the blue and the green LEDs. If the blue LED or the UV LED are combined with the wavelength conversion layers to generate the light of different wavelengths, the manufacturing cost and the commercialization difficulty will increase. In order to achieve the mass production and the commercialization of the multi-color LED display, an embodiment of the present application discloses the multi-wavelength LED on a wafer (the chip on wafer (COW) stage) comprising the InGaN material to simplify the production of the multi-color LED display, thereby improving the production efficiency and reducing the costs.

In an embodiment, the multi-wavelength LED can be the first light-emitting unit 10, the second light-emitting unit 20, or the third light-emitting unit 30 illustrated in FIGS. 3-12. The multi-wavelength LED includes the first semiconductor layer 210, the second semiconductor layer 220, and the active layer 230 located between the first semiconductor layer 210 and the second semiconductor layer 220. The active layer 230 can emit the light with a peak wavelength λ under a bias voltage or a current. The peak wavelength λ of the multi-wavelength LED can be modulated by changing or controlling the voltage or the current.

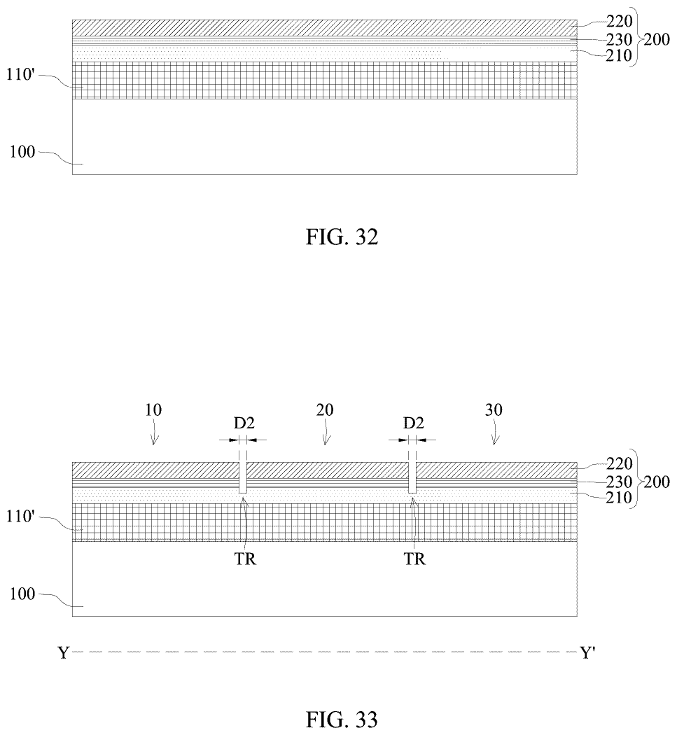

FIGS. 32-35 illustrate the cross-sectional views of the manufacturing method of the monolithic array chip 1′, 2′, 3′, 4′, 5′, 6′, 7′, 8′, 9′, 10′ along the line Y-Y′ in FIGS. 3-12. The dimension with the same symbol shown in FIGS. 32-35 is close to the dimension disclosed in FIGS. 13-14, and that will not be described again here. In the embodiment, the first semiconductor layer 210, the second semiconductor layer 220 and the active layer 230 all include Group III nitride materials, such as GaN, InGaN, AlGaN or

AlInGaN. The sub-pixel composed of the first light-emitting unit 10, the second light-emitting unit 20, or the third light-emitting unit 30 capable of emitting the red light, the green light, and the blue light include the same semiconductor structure and the material. In the embodiment, a porous region 110′ including the group III nitride semiconductor material is disposed between the substrate 100 and the first semiconductor layer 210, so that the light-emitting units composed of the same semiconductor stack 200 capable of emitting the multiple wavelengths. The multiple light-emitting units can emit the red light, the green light and the blue light. During the epitaxial growth process of the first semiconductor layer 210, the second semiconductor layer 220 and the active layer 230, the pores of the porous region 110′ can reduce the stress in the group III nitride semiconductor layer, so that the epitaxial quality can be improved during the epitaxial growth of the InGaN active layer 230 with high indium (In) content, and the active layer 230 can emit a longer wavelength than that of the blue light under a bias voltage or a current, such as the green light or the red light.

In an embodiment, by changing the bias voltage or the current, the peak wavelength λ can be controlled within the wavelength range of 40 nm, 50 nm, 60 nm, 70 nm or 80 nm. In another embodiment, the peak wavelength λ can be controlled within the wavelength range of 100 nm, 110 nm, 120 nm, 130 nm, 140 nm, 150 nm, 160 nm, 170 nm, 180 nm, 190 nm, 200 nm, 400 nm or 450 nm. By changing the bias voltage or the current and the size or the shape of the LED, the peak wavelength λ of the LED can be modulated. By changing the bias voltage or the current driving conditions, the peak wavelength λ of the light-emitting unit can be continuously changed within the range of the bias voltage or the current driving conditions. For example, the wavelength can be continuously changed in a range between 400 nm-850 nm.

In an embodiment, as shown in FIGS. 3-12, by providing a porous region 110′ (not shown) between the substrate 100 and the first semiconductor layer 210, the monolithic array wafer l′, 2′, 3′, 4′, 5′, 6′, 7′, 8′, 9′, 10′ includes the first semiconductor layer 210; the common electrode 41 located on the first semiconductor layer 210; the first light-emitting unit 10 with the first electrode 11 located on the first semiconductor layer 210, and the first light-emitting unit 10 including a first top view area; the second light-emitting unit 20 with the second electrode 21 located on the first semiconductor layer 210, and the second light-emitting unit 20 including a second top-view area; and the third light-emitting unit 30 with the third electrode 31 located on the first semiconductor layer 210, and the third light-emitting unit 30 including a third top-view area, wherein the first light-emitting unit 10, the second light-emitting unit 20, and the third light-emitting unit 30 are separated from each other by the trench TR. The first light-emitting unit 10 emits the green light (or the peak wavelength λ within the range of 510-560 nm) under the first driving condition. The second light-emitting unit 20 emits the red light (or the peak wavelength λ within the range of 600-660 nm) under the second driving condition. The third light-emitting unit 30 emits the blue light (or the peak wavelength λ within the range of 430-460 nm) under the third driving condition.

In an embodiment, the porous region 110′ and the substrate 100 can be selectively removed during the subsequent wafer processing.

In an embodiment, the first, second and third driving conditions may include the first, second and third current densities. In an embodiment, the first, second and third driving conditions may include the first, second and third power densities. Since the power, current and voltage are related according to P=IV, the driving conditions can be changed by changing the power, power density, current, current density or voltage supplied to the LED.

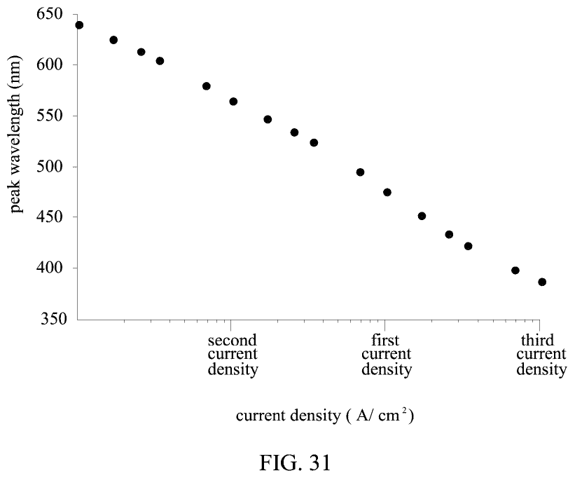

FIG. 31 illustrates the first, second and third light-emitting units 10, 20, 30 of the monolithic array chips 1′, 2′, 3′, 4′, 5′, 6′, 7′, 8′, 9′, 10′ comprise different peak wavelengths under different driving current densities. The peak wavelength λ of the first, second, and third light-emitting units 10, 20, 30 are changed by changing the current (Ampere, A) or the current density (in A/cm²) provided to the first, second, and third light-emitting units 10, 20, and 30. When the current or current density increases, the peak wavelength λ of the first, second, and third light-emitting units 10, 20, and 30 reduces. When the current or current density reduces, the peak wavelength λ of the first, second, and third light-emitting units 10, 20, 30 increases.

In an embodiment, the peak wavelength λ of the first, second, and third light-emitting units 10, 20, and 30 can be independently controlled by changing the current density. For example, the first light-emitting unit 10 can emit the green light at the first current density. The second light-emitting unit 20 can emit the red light at the second current density, and the third light-emitting unit 30 can emit the blue light at the third current density, wherein the third current density is larger than the first current density, and/or the first current density is larger than the second current density.

In an embodiment, as shown in FIG. 3, when the first, second and third light-emitting units 10, 20 and 30 include different top-view areas, for example, the second top-view area of the second light-emitting unit 20 is larger than the first top-view area of the first light-emitting unit 10, and/or the first top-view area of the first light-emitting unit 10 is larger than the third top-view area of the third light-emitting unit 30, the same current is injected into the first, the second and third light-emitting units 10, 20, 30 to provide different current densities in the first, second, and third light-emitting units 10, 20, 30, so that the third current density injected into the third light-emitting unit 30 is larger than the first current density injected into the first light-emitting unit 10, and/or the first current density injected into the first light-emitting unit 10 is larger than the second current density injected into the second light-emitting unit 20. The first light-emitting unit 10 can emit the green light under the first current density, the second light-emitting unit 20 can emit the red light under the second current density, and the third light-emitting unit 30 can emit the blue light under the third current density.

In an embodiment, as shown in FIG. 7, when the first, second and third light-emitting units 10, 20, 30 include the same top view area, different currents are injected into the first, second and third light-emitting units 10, 20, 30 to provide different current densities in the first, second and third light-emitting units 10, 20, 30. For example, the third current injected into the third light-emitting unit 30 is larger than the first current injected into the light-emitting unit 10, and/or the first current injected into the first light-emitting unit 10 is larger than the second current injected into the second light-emitting unit 20, so that the third current density injected into the third light-emitting unit 30 is larger than the first current density injected into the first light-emitting unit 10, and/or the first current density injected into the first light-emitting unit 10 is larger than the second current density injected into the second light-emitting unit 20. The first light-emitting unit 10 can emit the green light under the first current density, the second light-emitting unit 20 can emit the red light under the second current density, and the third light-emitting unit can emit the blue light under the third current density.

In the embodiment, the light-emitting units 10, 20, 30 can be used as the light-emitting unit G (green sub-pixel) that can emit the green light, the light-emitting unit R (red sub-pixel) that can emit the red light, and the light-emitting unit B (blue sub-pixel) that can emit the blue light as shown in FIG. 1. The common electrode 41 as the first electrical contact and the second electrical contact (the first electrode 11, the second electrode 21 and the third electrode 31) located on each light-emitting unit 10, 20, 30 can selectively control the luminescence of each light-emitting unit 10, 20, 30 of the monolithic array chip 1′, 2′, 3′, 4′, 5′, 6′, 7′, 8′, 9′, 10′. For example, only light up the blue sub-pixel, only light up the green sub-pixel, or only light up the red sub-pixel. In addition, multiple sub-pixels can also be combined to emit the blue-green light, the blue-red light, the red-green light, or the red-green-blue light.

In an embodiment, FIGS. 32-33 illustrate the manufacturing method of the monolithic array chip 1′, 2′, 3′, 4′, 5′, 6′, 7′, 8′, 9′, 10′. In an embodiment, FIG. 33 illustrates a cross-sectional view along the line Y-Y′ in FIGS. 3-12 before forming the electrode. As shown in FIG. 32, the manufacturing method of the monolithic array chip 1′, 2′, 3′, 4′, 5′, 6′, 7′, 8′, 9′ or 10′ includes providing the substrate 100, forming the semiconductor stack 200 on the substrate 100, and forming a porous region 110′ between the substrate 100 and the semiconductor stack 200. The substrate 100 includes, but is not limited to, a sapphire substrate, a silicon substrate, a silicon carbide substrate, or other semiconductor substrates. The semiconductor stack 200 is formed on the substrate 100, for example, by using a metal organic vapor deposition (MOCVD) method to sequentially form the epitaxial stack including the buffer layer (not shown), the porous region 110′, the first semiconductor layer 210, and the active layer. 230, and the second semiconductor layer 220 on an upper surface of the substrate 100. As shown in FIG. 33, a mask (not shown) is used to selectively remove a part of the epitaxial stack, expose a part of the upper surface of the epitaxial stack, and form a trench TR, for example, exposing the upper surface of the first semiconductor layer 210. Thereby, the patterns of the plurality of light-emitting units 10, 20, 30 are defined on different areas of the substrate 100 to form the light-emitting units 10, 20, and 30 comprising the active layers 230 of the same indium (In) composition. In the embodiment, the first semiconductor layer 210, the active layer 230, and the second semiconductor layer 220 formed on the porous region 110′ include the same Group III nitride material.

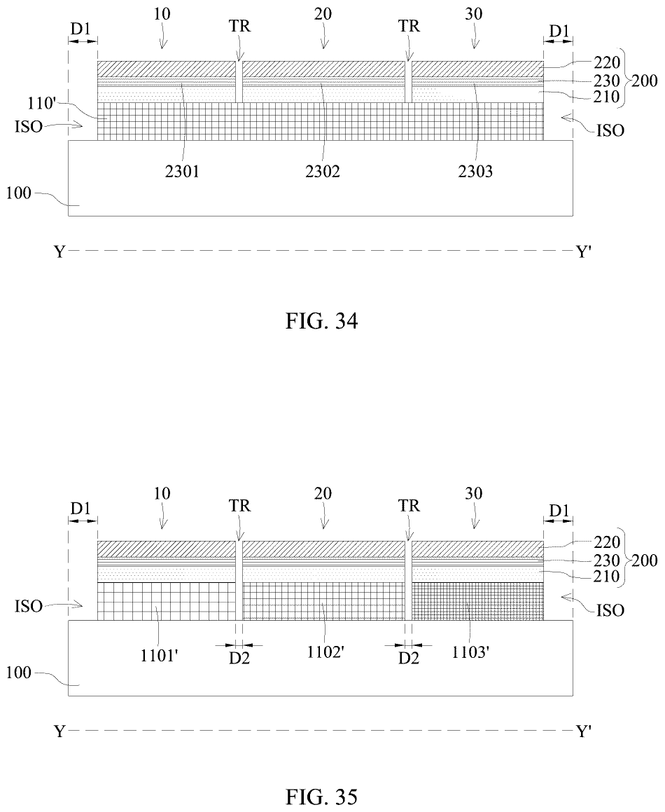

In another embodiment, FIG. 34 illustrates the manufacturing method of the monolithic array chip 1′, 2′, 3′, 4′, 5′, 6′, 7′, 8′, 9′, 10′. In an embodiment, FIG. 34 illustrates a cross-sectional view along the line Y-Y′ in FIGS. 3-12 before forming the electrode. As shown in FIG. 34, the manufacturing method of the monolithic array chip 1′, 2′, 3′, 4′, 5′, 6′, 7′, 8′, 9′ or 10′ includes providing the substrate 100 and forming the porous region 110′ on the substrate 100. The active layers 2301, 2302, 2303 with different indium (In) compositions are formed on different areas of the porous region 110′ through a mask (not shown). The mask may be a patterned photoresist layer, or may be other photoresist materials, such as silicon dioxide. Taking the patterned photoresist layer as an example, it can be formed using the conventional techniques, such as photolithography or electron-beam lithography. For example, a photoresist layer is coated on the epitaxial stack, and the photoresist is exposed using an appropriate light source to transfer the pattern onto the photoresist layer, thereby defining the patterns of the plurality of light-emitting units 10, 20, 30 on different areas of the porous region 110′ to form the active layers 2301, 2302, 2303 having different indium (In) compositions of light-emitting units 10, 20, 30.

In another embodiment, FIG. 35 illustrates the manufacturing method of the monolithic array chip 1′, 2′, 3′, 4′, 5′, 6′, 7′, 8′, 9′, 10′. In an embodiment, FIG. 35 illustrates the cross-sectional view along the line Y-Y′ in FIGS. 3-12 before forming the electrode. As shown in FIG. 35, the manufacturing method of the monolithic array chip 1′, 2′, 3′, 4′, 5′, 6′, 7′, 8′, 9′, 10′ includes providing the substrate 100 and forming the plurality of porous regions 1101′, 1102′, 1103′ on the substrate 100. In the embodiment, the plurality of porous regions 1101′, 1102′, 1103′ comprises different porosity. The active layers 230 of light-emitting units 10, 20, 30 formed on different porous regions 1101′, 1102′, 1103′ comprises the same or different indium (In) compositions. The higher the porosity, the wider the range in which the peak wavelengths of the light-emitting units 10, 20, 30 can be modulated. For example, the porosity of the porous region 1102′ formed under the second light-emitting unit 20 for emitting the red light is greater than the porosity of the porous region 1103′ formed under the third light-emitting unit 30 for emitting the blue light. The porosity of the porous region 1101′ formed under the first light-emitting unit 10 for emitting the green light is greater than the porosity of the porous region 1103′ formed under the third light-emitting unit 30 for emitting the blue light. The porosity of the porous region 1101′ formed under the first light-emitting unit 10 for emitting the green light is greater than the porosity of the porous region 1102′ formed under the second light-emitting unit 20 for emitting the red light.

The elements of some of the above embodiments are described so that those with ordinary knowledge in the technical field to which this disclosure belongs can better understand the viewpoints of the embodiments of the disclosure. Those with ordinary skill in the art to which this disclosure belongs should understand that they can design or modify other processes and structures based on the embodiments of the disclosure to achieve the same purposes and/or advantages as the embodiments introduced here. Those with ordinary knowledge in the technical field to which this disclosure belongs should also understand that such equivalent structures do not deviate from the spirit and scope of the disclosure, and they can do various things without departing from the spirit and scope of this disclosure. Various changes, substitutions and replacements. Therefore, the protection scope of the present disclosure shall be subject to the scope of the appended patent application. In addition, although the disclosure has been disclosed with several preferred embodiments as above, this is not intended to limit the disclosure.

Reference throughout the specification to features, advantages, or similar language does not imply that all features and advantages that can be realized with the present disclosure should or can be realized in any single embodiment of the present disclosure. In contrast, language referring to features and advantages is to be understood to mean that a particular feature, advantage, or characteristic described in connection with the embodiment is of at least an embodiment of the present disclosure. Thus, discussions of features and advantages, and similar language, throughout the specification may, but are not necessarily, representative of the same embodiments.

Furthermore, the described features, advantages, and characteristics of the present disclosure may be combined in any suitable manner in one or more embodiments. From the description herein, those skilled in the relevant art will appreciate that the present disclosure may be practiced without one or more of the specific features or advantages of a particular embodiment. In other instances, additional features and advantages may be identified in certain embodiments that may not be present in all embodiments of the present disclosure.

What is claimed is:

1. A monolithic array chip, including:
a first semiconductor layer;
a common electrode located on the first semiconductor layer;
a first light-emitting unit with a first electrode located on the first semiconductor layer;
a second light-emitting unit with a second electrode located on the first semiconductor layer; and
a third light-emitting unit with a third electrode located on the first semiconductor layer,
wherein the first light-emitting unit, the second light-emitting unit, and the third light-emitting unit are separated from each other by a trench.

2. The monolithic array chip according to claim 1, wherein the trench includes a minimum width less than or equal to 3 μm.

3. The monolithic array chip according to claim 1, wherein the first light-emitting unit, the second light-emitting unit and the third light-emitting unit emit the same peak wavelength.

4. The monolithic array chip according to claim 3, further including a first wavelength conversion layer located on the first light-emitting unit, the first wavelength conversion layer absorbing the peak wavelength to emit a first converted wavelength different from the peak wavelength.

5. The monolithic array chip according to claim 3, further including a second wavelength conversion layer located on the second light-emitting unit, the second wavelength conversion layer absorbs the peak wavelength to emit a second converted wavelength different from the peak wavelength.

6. The monolithic array chip according to claim 1, wherein the monolithic array chip includes a first light-emitting area capable of emitting the red light located on the first light-emitting unit, a second light-emitting area capable of emitting the green light located on the second light-emitting unit, and a third light-emitting area capable of emitting the blue light located on the third light-emitting unit.

7. The monolithic array chip according to claim 1, wherein the monolithic array chip includes a side having a length not greater than 90 μm, 75 μm, 60 μm, 50 μm, 40 μm or not more than 30 μm.

8. The monolithic array chip according to claim 1, wherein the first light-emitting unit, the second light-emitting unit, and the third light-emitting unit each includes an area not larger than 4900 μm², 3600 μm², 2500 μm², 1600 μm², 900 μm², 400 μm², or 100 μm².

9. The monolithic array chip according to claim 1, wherein the common electrode, the first electrode, the second electrode, and the third electrode each includes an area less than 10 μm².

10. The monolithic array chip according to claim 1, wherein the common electrode is spaced apart from one of the first electrode, the second electrode and the third electrode by a spacing, and the space is less than or equal to ½ or ⅓ of a length of a side of the monolithic array chip.

11. The monolithic array chip according to claim 1, wherein the first light-emitting unit, the second light-emitting unit, and the third light-emitting unit include different top view areas.

12. The monolithic array chip according to claim 1, wherein any two light-emitting units of the first light-emitting unit, the second light-emitting unit and the third light-emitting unit include the same top view areas.

13. The monolithic array chip according to claim 1, wherein each of the first light-emitting unit and the third light-emitting unit includes a top view area that is larger than the top view area of the second light-emitting unit.

14. The monolithic array chip according to claim 13, wherein a ratio between the top view area of each of the first light-emitting unit and the third light-emitting unit and the top view area of the second light-emitting unit is 1.3-1.7.

15. The monolithic array chip according to claim 1, wherein each of the first light-emitting unit and the third light-emitting unit includes a top view area smaller than the top view area of the second light-emitting unit.

16. The monolithic array chip according to claim 15, wherein a ratio between the top view area of the second light-emitting unit and the top view area of each of the first light-emitting unit and the third light-emitting unit have is 1.7-2.3.

17. The monolithic array chip according to claim 14, wherein the second light-emitting unit and the common electrode are located on a diagonal line on the monolithic array chip.

18. The monolithic array chip according to claim 1, wherein any two light-emitting units of the first light-emitting unit, the second light-emitting unit and the third light-emitting unit are located on a diagonal line on the monolithic array chip, and each of the any two light-emitting units includes one side parallel to each other.

19. The monolithic array chip according to claim 18, wherein there is a distance between the sides of the any two light-emitting units that is greater than the minimum width of the trench.

20. A light-emitting module including:
a circuit board; and
a plurality of monolithic array chips according to any one of claim 4 to claim 20 are located on the circuit board, wherein the plurality of monolithic array chips are separated from each other by a separation lane including a width less than 1000 μm.
